(19) United States
(12) Patent Application Publication
(10) Pub. No.: US 2010/0022070 A1
(43) Pub. Date: Jan. 28, 2010

(54) METHOD FOR MANUFACTURING SOI SUBSTRATE

(75) Inventor: Ryota Imahayashi, Isehara (JP)

Correspondence Address: ERIC ROBINSON, PMB 955, 21010 SOUTHBANK ST., POTOMAC FALLS, VA, 20165, US

(73) Assignee: Semiconductor Energy Laboratory Co., Ltd., Atsugi-shi (JP)

(21) Appl. No.: 12/505,720

(22) Filed: Jul. 20, 2009

(30) Foreign Application Priority Data
Jul. 22, 2008 (JP) 2008-189111

(51) Int. Cl. H01L 21/762

(52) U.S. Cl. 438/458; 257/E21.568

(57) ABSTRACT

It is an object to provide a method for, after a semiconductor film is separated, reprocessing a separated bond substrate into a reprocessed bond substrate which can be used for manufacturing an SOI substrate. The method for, after a semiconductor film is separated, reprocessing a separated bond substrate into a reprocessed bond substrate which can be used for manufacturing an SOI substrate includes the steps of forming an insulating film over a bond substrate; adding ions from a surface of the bond substrate to form an embrittlement layer; bonding the bond substrate to a glass substrate with the insulating film interposed therebetween; separating, at the embrittlement layer, the bond substrate into a semiconductor film which is bonded to the glass substrate with the insulating film interposed therebetween and a separated bond substrate; performing first wet etching using a solution containing hydrofluoric acid as an etchant on the separated bond substrate; performing second wet etching using an organic alkaline aqueous solution as an etchant on the separated bond substrate; performing thermal oxidation treatment on the separated bond substrate in an oxidizing atmosphere to which a gas containing halogen is added to form an oxide film on a surface of the separated bond substrate; performing third wet etching using a solution containing hydrofluoric acid as an etchant on the oxide film; and forming a reprocessed bond substrate by performing polishing on the separated bond substrate.

### BACKGROUND OF THE INVENTION

1. Field of the Invention

The present invention relates to a method for manufacturing a silicon-on-insulator (SOI) substrate.

2. Description of the Related Art

In recent years, integrated circuits using a silicon-on-insulator (SOI) substrate in which a thin single crystal semiconductor layer is provided on an insulating surface, instead of a bulk silicon wafer, have been developed. By utilizing characteristics of the thin single crystal silicon film formed on the insulating surface, transistors in the integrated circuit can be separated from each other completely. Further, since the transistors can be formed as fully depleted transistors, a semiconductor integrated circuit with high added value such as high integration, high-speed driving, and low power consumption can be realized.

As one of methods for manufacturing an SOI substrate, Smart Cut (registered trademark) can be given. By using Smart Cut, an SOI substrate having a single crystal silicon film can be manufactured not only over a silicon substrate but also over an insulating substrate such as a glass substrate (for example, see Patent Document 1). The outline of a method for manufacturing an SOI substrate having a single crystal silicon thin film over a glass substrate by Smart Cut is described below. First, a silicon dioxide film is formed on a surface of a single crystal silicon piece. Next, hydrogen ions are implanted into the single crystal silicon piece to form a hydrogen implanted layer at a predetermined depth in the single crystal silicon piece. Then, the single crystal silicon piece into which hydrogen ions are implanted is boned to a glass substrate with the silicon dioxide film interposed therebetween. After that, heat treatment is performed, whereby using the hydrogen implanted layer as a cleavage plane, the single crystal silicon piece into which hydrogen ions are implanted is separated as a thin film, and thus the single crystal silicon thin film can be formed over the glass substrate that has undergone the bonding. Smart Cut may be referred to as a hydrogen ion implantation separation method.

### [Reference]

### [Patent Document]

### [Patent Document 1] Japanese Published Patent Application No. 2004-87606

When an SOI substrate is manufactured by Smart Cut, after a bond substrate (a single crystal semiconductor substrate) is boned to a glass substrate, the bond substrate is separated, whereby a thin semiconductor film is formed over the glass substrate. Most part of the bond substrate which is bonded is separated from the glass substrate. However, the bond substrate separated from the glass substrate (a separated bond substrate) is subjected to reprocessing treatment, whereby it can be reused as a bond substrate for manufacturing an SOI substrate. By repeating the above steps, a plurality of semiconductor films for SOI substrates can be formed using one bond substrate; therefore, cost reduction and high efficiency in manufacturing an SOI substrate can be achieved.

However, many crystal defects are formed on a surface of the separated bond substrate from which a thin semiconductor film has been separated by Smart Cut and the planarity of the separated bond substrate is damaged severely. In particular, there is a problem in that in the case of using substrates of which coefficients of thermal expansion are different from each other, such as using a glass substrate as a base substrate and using as a single crystal silicon substrate as a bond substrate, on separation surfaces of a semiconductor film bonded to the glass substrate and the separated bond substrate, a thickness non-uniformity is formed. This thickness non-uniformity has a thickness of about 10 nm to 100 nm, and in the case of a rectangular bond substrate, for example, a thickness non-uniformity having an L shape or a reversed C shape is formed. There may be a problem in that, for example, in the case of reusing a bond substrate having a thickness non-uniformity on the surface for manufacturing an SOI substrate, a glass substrate and a bond substrate cannot be sufficiently bonded to each other.

As a method for removing thickness non-uniformity on a surface of a bond substrate and planarizing the surface, a chemical mechanical polishing (CMP) method is given. However, since a CMP method is a method in which a substrate surface is polished mechanically, there is a problem in that a polished portion (an amount of polishing) of the bond substrate is increased. That is, a removed portion of the bond substrate is increased in a reprocessing treatment process, and thus the number of reprocessing and using one bond substrate is reduced, which leads to an increase in cost.

In particular, in a peripheral portion of a bond substrate such as a commercial single crystal silicon wafer, there is a chamfer portion where a corner is chamfered in a peripheral portion; therefore, the peripheral portion of the bond substrate cannot be bonded to a glass substrate favorably. Accordingly, when the bond substrate is separated, a peripheral portion of a semiconductor film which should be bonded to the glass substrate remains in a peripheral portion of a separated bond substrate. When such a projection including the semiconductor film and the like exists in the peripheral portion of the bond substrate, a polished portion in using a CMP method is further increased.

### SUMMARY OF THE INVENTION

In view of the above problems, it is an object of one embodiment of the present invention to provide a method for, after a semiconductor film is separated, reprocessing a separated bond substrate into a reprocessed bond substrate which can be used for manufacturing an SOI substrate.

One embodiment of the present invention is a method for manufacturing an SOI substrate which includes the steps of forming an insulating film over a bond substrate; adding ions from a surface of the bond substrate to form an embrittlement layer; bonding the bond substrate to a glass substrate with the insulating film interposed therebetween; and separating, at the embrittlement layer, the bond substrate into a semiconductor film which is bonded to the glass substrate with the insulating film interposed therebetween and a separated bond substrate. The method for manufacturing an SOI substrate further includes the steps of performing wet etching on the separated bond substrate; performing thermal oxidation treatment on the separated bond substrate in an oxidizing atmosphere to which a gas containing halogen is added to form an oxide film on a surface of the separated bond substrate; performing wet etching on the oxide film; and forming a reprocessed bond substrate by performing polishing on the separated bond substrate to reuse the reprocessing bond substrate as a bond substrate.

Another embodiment of the present invention is a method for manufacturing an SOI substrate which includes the steps of forming an insulating film over a bond substrate; adding ions from a surface of the bond substrate to form an embrittlement layer; bonding the bond substrate to a glass substrate with the insulating film interposed therebetween; and separating, at the embrittlement layer, the bond substrate into a semiconductor film which is bonded to the glass substrate with the insulating film interposed therebetween and a separated bond substrate. The method for manufacturing an SOI substrate further includes the steps of performing first wet etching using a solution containing hydrofluoric acid as an etchant on the separated bond substrate; performing second wet etching using an organic alkaline aqueous solution as an etchant on the separated bond substrate; performing thermal oxidation treatment on the separated bond substrate in an oxidizing atmosphere to which a gas containing halogen is added to form an oxide film on a surface of the separated bond substrate; performing third wet etching using a solution containing hydrofluoric acid as an etchant on the oxide film; and forming a reprocessed bond substrate by performing polishing on the separated bond substrate to reuse the reprocessing bond substrate as a bond substrate.

Note that it is preferable to remove thickness non-uniformity generated on a separation surface of the separated bond substrate in separating the bond substrate in such a manner that first wet etching using a solution containing hydrofluoric acid as an etchant is performed on the separated bond substrate; second wet etching using an organic alkaline aqueous solution as an etchant is performed on the separated bond substrate; thermal oxidation treatment is performed on the separated bond substrate in an oxidizing atmosphere to which a gas containing halogen is added to form an oxide film on a surface of the separated bond substrate; and third wet etching using a solution containing hydrofluoric acid as an etchant is performed on the oxide film.

Further, it is preferable to remove a semiconductor film and an insulating film which remain in the peripheral portion of the separated bond substrate in separating the bond substrate in such a manner that first wet etching using a solution containing hydrofluoric acid as an etchant is performed on the separated bond substrate; second wet etching using an organic alkaline aqueous solution as an etchant is performed on the separated bond substrate; thermal oxidation treatment is performed on the separated bond substrate in an oxidizing atmosphere to which a gas containing halogen is added to form an oxide film on a surface of the separated bond substrate; third wet etching using a solution containing hydrofluoric acid as an etchant is performed on the oxide film; and polishing is performed on the separated bond substrate.

Further, the insulating film is preferably a single film or a stacked layer of a plurality of films selected from a silicon oxide film, a silicon nitride film, a silicon oxynitride film, and a silicon nitride oxide film. The silicon oxide film is preferably formed by a chemical vapor deposition method using an organosilane gas. In addition, the silicon oxide film is preferably formed by performing thermal oxidation on the bond substrate.

Further, a second insulating film is preferably formed in contact with the glass substrate. The second insulating film is preferably a silicon nitride film or a silicon nitride oxide film.

The bond substrate is preferably a single crystal silicon substrate. Further, the glass substrate is preferably an aluminosilicate glass substrate, a barium borosilicate glass substrate, or an aluminoborosilicate glass substrate.

The solution containing hydrofluoric acid is preferably a mixed solution containing hydrofluoric acid, ammonium fluoride, and a surfactant. Further, the organic alkaline aqueous solution is preferably an aqueous solution containing tetramethylammonium hydroxide. As the gas containing halogen, HCl is preferably used. The oxide film preferably contains halogen.

As the polishing, a chemical mechanical polishing (CMP) method is preferably used.

According to one embodiment of the present invention, a method for, after a semiconductor film is separated, reprocessing a separated bond substrate into a reprocessed bond substrate which can be used for manufacturing an SOI substrate can be provided.

### BRIEF DESCRIPTION OF THE DRAWINGS

In the accompanying drawings:

FIGS. 1A to 1C are views illustrating a method for manufacturing an SOI substrate according to an embodiment of the present invention;

FIGS. 2A to 2C are views illustrating the method for manufacturing an SOI substrate according to an embodiment of the present invention;

FIGS. 3A to 3C are views illustrating the method for manufacturing an SOI substrate according to an embodiment of the present invention;

FIGS. 4A to 4C are views illustrating the method for manufacturing an SOI substrate according to an embodiment of the present invention;

FIG. 5 is a view illustrating a separation surface of a separated bond substrate of an SOI substrate according to an embodiment of the present invention;

FIG. 6 is a view illustrating a manufacturing process of an SOI substrate according to an embodiment of the present invention;

FIGS. 7A to 7D are views illustrating a method for manufacturing a semiconductor device using an SOI substrate according to an embodiment of the present invention;

FIGS. 8A to 8C are views illustrating the method for manufacturing a semiconductor device using an SOI substrate according to an embodiment of the present invention;

FIG. 9 is a view illustrating a semiconductor device using an SOI substrate according to an embodiment of the present invention;

FIG. 10 is a view illustrating a semiconductor device using an SOI substrate according to an embodiment of the present invention;

FIGS. 11A and 11B are views illustrating a display device using an SOI substrate according to an embodiment of the present invention;

FIGS. 12A and 12B are views illustrating a display device using an SOI substrate according to an embodiment of the present invention;

FIGS. 13A to 13C are views illustrating an electronic device using an SOI substrate according to an embodiment of the present invention;

FIGS. 14A and 14C are views each illustrating an electronic device using an SOI substrate according to an embodiment of the present invention;

FIGS. 15A and 15B are photographs of a separation surface of a separated bond substrate of an SOI substrate according to an embodiment of the present invention;

FIGS. 16A and 16B are photographs of a separation surface of a separated bond substrate of an SOI substrate according to an embodiment of the present invention; and

FIG. 17 is a photograph of a separation surface of a separated bond substrate of an SOI substrate according to an embodiment of the present invention.

### DETAILED DESCRIPTION OF THE INVENTION

Embodiments of the present invention will be described below with reference to the accompanying drawings. However, the present invention can be implemented in various modes, and it is easily understood by those skilled in the art that modes and details can be variously changed without departing from the scope and the spirit of the present invention. Therefore, the present invention should not be construed as being limited to the following description of the embodiments. Note that in the drawings of this specification, the identical portions or portions having a similar function are denoted by the identical reference numerals, and description thereon may be omitted.

### Embodiment 1

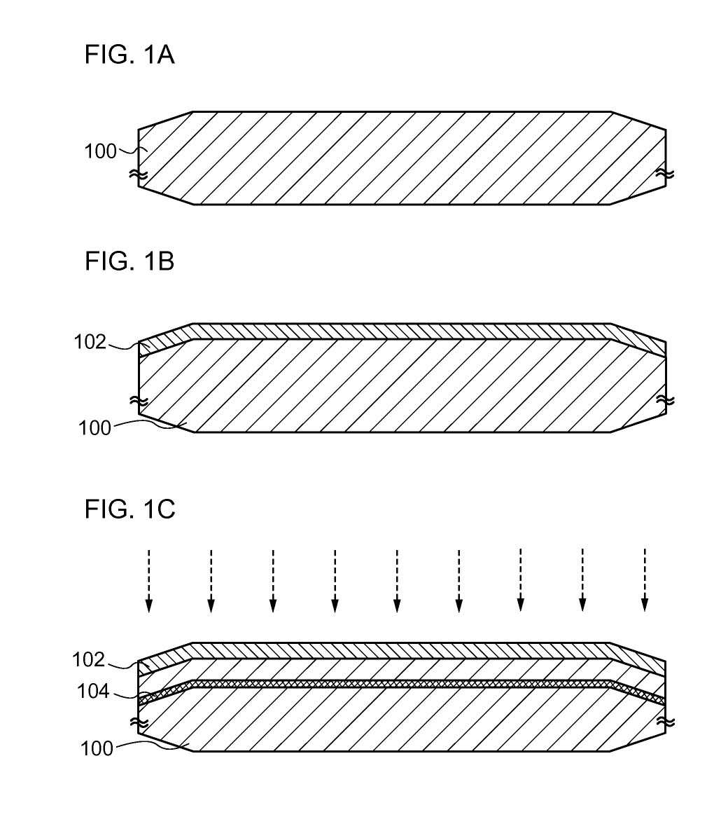

In a method for manufacturing an SOI substrate according to this embodiment, an SOI substrate is manufactured in such a manner that a semiconductor film separated from a semiconductor substrate which is a bond substrate is bonded to a base substrate. The separated bond substrate from which the semiconductor film has been separated is subjected to reprocessing treatment and reused as a bond substrate. Hereinafter, with reference to FIGS. 1A to 1C, FIGS. 2A to 2C, FIGS. 3A to 3C, FIGS. 4A to 4C, FIG. 5, and FIG. 6 which illustrate steps of manufacturing an SOI substrate, one of methods for manufacturing an SOI substrate of this embodiment will be described.

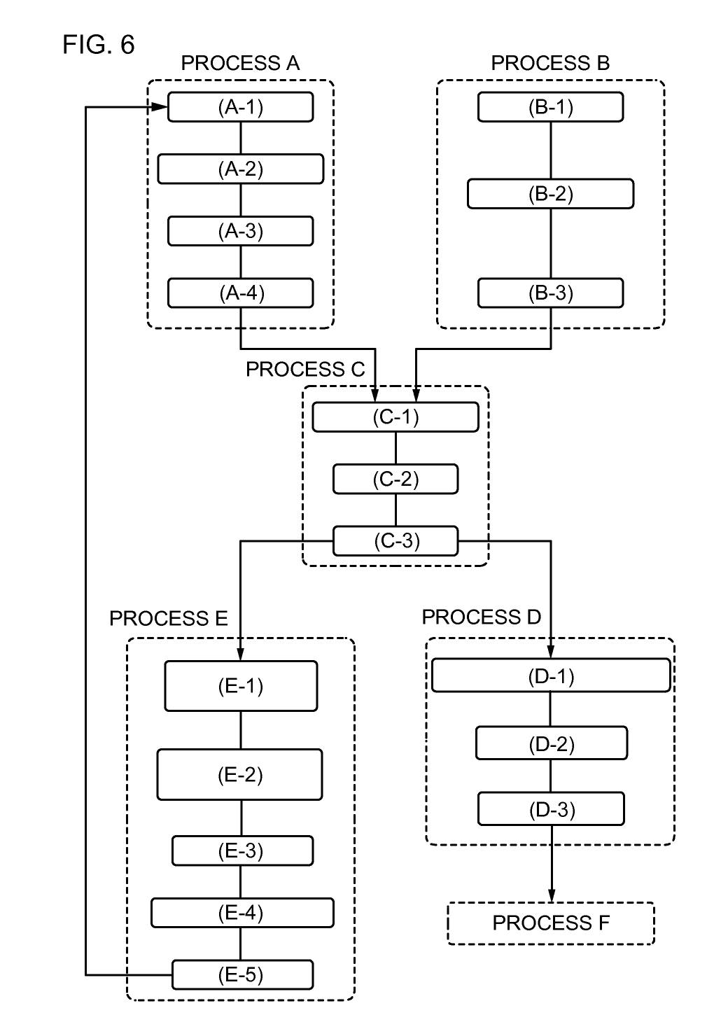

First, a process of forming an embrittlement layer 104 in a bond substrate 100 and preparing for bonding the bond substrate 100 to a glass substrate 120 which is a base substrate will be described. The following process corresponds to Process A (bond substrate process) in FIG. 6.

First, the bond substrate 100 as illustrated in FIG. 1A is prepared (this step corresponds to a step A-1 in FIG. 6). The bond substrate 100 can be a commercially-available semiconductor substrate such as a single crystal semiconductor substrate or a polycrystalline semiconductor substrate, which is formed using silicon, germanium, or the like. Alternatively, a single crystal semiconductor substrate or a polycrystalline semiconductor substrate formed of a compound semiconductor such as gallium arsenide or indium phosphide can be used as the bond substrate 100. The size of a commercially-available silicon substrate is typically 5 inches (125 mm) in diameter, 6 inches (150 mm) in diameter, 8 inches (200 mm) in diameter, 12 inches (300 mm) in diameter, and 16 inches (400 mm) in diameter, and a typical shape thereof is a circular shape. Further, in a peripheral portion of a commercially-available silicon substrate, there is a chamfer portion for preventing chipping or cracking as illustrated in FIG. 1A. Note that the silicon substrate is not limited to a circular shape, and a silicon substrate processed to have a rectangular shape or the like can also be used. In the description given below, a case in which a rectangular single crystal silicon substrate is used as the bond substrate 100 will be described.

Next, as illustrated in FIG. 1B, after a surface of the bond substrate 100 is cleaned, an insulating film 102 is formed over the bond substrate 100 (this step corresponds to a step A-2 in FIG. 6). The insulating film 102 may be formed using either a single insulating film or a stack of a plurality of insulating films. For example, in this embodiment, silicon oxide is used for the insulating film 102. As a film which forms the insulating film 102, an insulating film which contains silicon as a component, such as a silicon oxide film, a silicon nitride film, a silicon oxynitride film, or a silicon nitride oxide film, can be used. Note that it is preferable that the surface of the bond substrate 100 be cleaned using a sulfuric acid/hydrogen peroxide mixture (SPM), an ammonium hydroxide/hydrogen peroxide mixture (APM), a hydrochloric acid/hydrogen peroxide mixture (HPM), dilute hydrogen fluoride (DHF), or the like.

Note that in this specification, a “silicon oxynitride film” means a film that contains more oxygen atoms than nitrogen atoms, and oxygen, nitrogen, silicon, and hydrogen at concentrations ranging from 50 atomic % to 70 atomic %, 0.5 atomic % to 15 atomic %, 25 atomic % to 35 atomic %, and 0.1 atomic % to 10 atomic %, respectively, when they are measured by RBS (Rutherford Backscattering Spectrometry) and HFS (Hydrogen Forward Scattering). Further, a “silicon nitride oxide film” means a film that contains more nitrogen atoms than oxygen atoms, and oxygen, nitrogen, silicon, and hydrogen at concentrations ranging from 5 atomic % to 30 atomic %, 20 atomic % to 55 atomic %, 25 atomic % to 35 atomic %, and 10 atomic % to 30 atomic %, respectively, when they are measured by RBS and HFS. Note that percentages of nitrogen, oxygen, silicon, and hydrogen fall within the ranges given above, where the total number of atoms contained in the silicon oxynitride or the silicon nitride oxide is defined as 100 atomic %.

In the case of using silicon oxide for the insulating film 102, the insulating film 102 can be formed using a mixed gas of silane and oxygen, a mixed gas of TEOS (tetraethoxysilane) and oxygen, or the like by a vapor deposition method such as thermal CVD, plasma CVD, atmospheric pressure CVD, or bias ECRCVD. In this case, a surface of the insulating film 102 may be densified by oxygen plasma treatment.

Alternatively, a silicon oxide film formed by a chemical vapor deposition method using an organosilane gas may be used as the insulating film 102. For the organosilane gas, the following compounds containing silicon can be used: tetraethoxysilane (TEOS, chemical formula: Si(OC₂H₅)₄), tetramethylsilane (TMS, chemical formula: Si(CH₃)₄), tetramethylcyclotetrasiloxane (TMCTS), octamethylcyclotetrasiloxane (OMCTS), hexamethyldisilazane (HMDS), triethoxysilane (SiH(OC₂H₅)₃), trisdimethylaminosilane (SiH(N(CH₃)₂)₃), and the like.

Alternatively, the insulating film 102 can be formed using an oxide film obtained by oxidizing the bond substrate 100. Thermal oxidation treatment for forming the oxide film may be dry oxidation or may be performed in an oxidizing atmosphere to which a halogen-containing gas is added. As the halogen-containing gas, one or plural kinds of gases selected from HCl, HF, NF₃, HBr, Cl₂, ClF, BCl₃, F₂, Br₂, and the like can be used. Note that in FIG. 1B, the insulating film 102 is formed only on one of the surfaces of the bond substrate 100; however, this embodiment is not limited thereto. In the case of forming the insulating film 102 using an oxide film which is obtained by oxidizing the bond substrate 100, the insulating film 102 may be formed so as to cover the bond substrate 100.

For example, thermal treatment is carried out in an atmosphere containing HCl at a ratio of 0.5 volume % to 10 volume % (preferably, 3 volume %) with respect to oxygen at a temperature higher than or equal to 700° C. and lower than or equal to 1100° C. For example, heat treatment may be performed at about 950° C. The treatment time may be 0.1 hours to 6 hours, preferably, 2.5 hours to 3.5 hours. The thickness of the oxide film to be formed can be set in the range of 15 nm to 1100 nm (preferably 50 nm to 150 nm), for example, 100 nm.

By this thermal oxidation treatment in the atmosphere containing halogen, halogen can be contained in the oxide film. When the oxide film includes the halogen element at a concentration of 1×10¹⁷ atoms/cm³ to 1×10²¹ atoms/cm³, the oxide film captures a heavy metal (e.g. Fe, Cr, Ni, Mo) which is an extrinsic impurity; therefore, contamination of a semiconductor film to be formed later can be prevented.

The insulating film 102 containing halogen such as chlorine by HCl oxidation or the like can serve to getter impurities (e.g. mobile ions of Na) which adversely affect the bond substrate 100. Specifically, by heat treatment which is performed after the insulating film 102 is formed, impurities included in the bond substrate 100 are separated out to the insulating film 102, reacted with halogen atom (e.g. a chlorine atom), and captured. Thus, the impurities captured in the insulating film 102 can be fixed to prevent contamination of the bond substrate 100. Further, in the case of bonding the insulating film 102 to a glass substrate, the insulating film 102 can serve as a film which fixes impurities such as Na included in a glass.

Moreover, the halogen element included in the oxidation treatment terminates defects on the surface of the bond substrate 100; therefore, the local level density of an interface between the oxide film and the bond substrate 100 can be reduced.

In the case of using, as a base substrate, a glass substrate which includes impurities which decrease reliability of a semiconductor device, such as an alkali metal or an alkaline earth metal, the insulating film 102 preferably includes at least one or more films which can prevent the impurities in the base substrate from diffusing into the semiconductor film of the SOI substrate. As such a film, a silicon nitride film, a silicon nitride oxide film, or the like can be given. With such a film included in the insulating film 102, the insulating film 102 can serve as a barrier film.

In the case of using silicon nitride for the insulating film 102, the insulating film 102 can be formed using a mixed gas of silane and ammonium by a vapor deposition method such as plasma CVD. In addition, in the case of using silicon nitride oxide for the insulating film 102, the insulating film 102 can be formed using a mixed gas of silane and ammonium or a mixed gas of silane and dinitrogen monoxide by a vapor deposition method such as a plasma CVD method.

For example, in the case of forming a barrier film having a single-layer structure as the insulating film 102, the insulating film 102 can be a silicon nitride film or a silicon nitride oxide film with a thickness greater than or equal to 15 nm and less than or equal to 30 nm.

In the case of forming a barrier film with a two-layer structure as the insulating film 102, the upper layer is formed using an insulating film with a high barrier property. The upper layer of the insulating film can be formed using, for example, a silicon nitride film or a silicon nitride oxide film with a thickness of 15 nm to 300 nm. These films have a high blocking effect for preventing impurity diffusion, but their internal stress is also high. Therefore, as the lower layer of the insulating film which is in contact with the bond substrate 100, a film with an effect of relieving the stress of the upper layer of the insulating film is preferable. As the insulating film having the effect of relieving the stress of the upper layer of the insulating film, a silicon oxide film, a silicon oxynitride film, a thermal oxide film formed by thermally oxidizing the bond substrate 100, and the like are given. The lower layer of the insulating film can be formed to have a thickness greater than or equal to 5 nm and less than or equal to 200 nm.

In order that the insulating film 102 serve as a blocking film, the insulating film 102 is preferably formed using a combination of a silicon oxide film and a silicon nitride film, a silicon oxynitride film and a silicon nitride film, a silicon oxide film and a silicon nitride oxide film, a silicon oxynitride film and a silicon nitride oxide film, or the like.

Next, as illustrated in FIG. 1C, the bond substrate 100 is irradiated with an ion beam including ions accelerated by an electric field through the insulating film 102, as indicated by arrows. Thus, an embrittlement layer 104 having microvoids is formed in a region at a predetermined depth from the surface of the bond substrate 100 (this step corresponds to a step A-3 in FIG. 6). The depth of the region where the embrittlement layer 104 is formed can be adjusted by the acceleration energy of the ion beam and the angle at which the ion beam enters. The acceleration energy can be adjusted by an acceleration voltage, dose, or the like. The embrittlement layer 104 is formed in a region at the same depth or substantially the same depth as the average depth at which the ions have entered. The thickness of a semiconductor film 124 which is to be separated from the bond substrate 100 later is determined based on the depth at which the ions are added. The depth at which the embrittlement layer 104 is formed can be set in the range of, for example, greater than or equal to 50 nm and less than or equal to 500 nm, preferably greater than or equal to 50 nm and less than or equal to 200 nm; for example, the depth is preferably about 100 nm from the surface of the bond substrate 100. Note that in this embodiment, the ion irradiation is performed after the insulating film 102 is formed; however, the ion irradiation may be performed before the insulating film 102 is formed.

The ions are preferably added to the bond substrate 100 by an ion doping method in which mass separation is not performed because the takt time can be shortened. However, in the case of adding the ions by an ion doping method, as compared to an ion implantation method in which mass separation is performed, some variations in depth at which the ions are added occur; therefore, the bond substrate is damaged by hydrogen ions to a depth of about 300 nm to 700 nm, for example, about 500 nm, from the surface in some cases.

When hydrogen (H₂) is used for a source gas, H⁺, H₂⁺, and H₃⁺ can be produced by exciting a hydrogen gas. The proportion of ion species produced from the source gas can be changed by adjusting a plasma excitation method, pressure in an atmosphere for generating plasma, the amount of supplying the source gas, and the like. In the case where the ion irradiation is performed by an ion doping method, it is preferable that H₃⁺ be contained at 70% or more with respect to the total amount of H⁺, H₂⁺, and H₃⁺ in the ion beam, and it is more preferable that the proportion of H₃⁺ be 80% or more. When H₃⁺ occupies 70% or more, the proportion of H₂⁺ ions in the ion beam gets smaller relatively, which results in lower variation in the average depth at which the hydrogen ions in the ion beam enter. Consequently, the ion addition efficiency improves and the takt time can be shortened.

H₃⁺ has larger mass than H⁺ and H₂⁺. When the ion beam containing a larger proportion of H₃⁺ is compared with the ion beam containing a larger proportion of H⁺ and H₂⁺, the former can add hydrogen to a shallower region of the bond substrate 100 than the latter even though the acceleration voltage at the time of doping is the same. Moreover, the former has a steep concentration profile of hydrogen added to the bond substrate 100 in a thickness direction, the embrittlement layer 104 itself can be formed to be thinner.

In the case where the ion irradiation is performed by an ion doping method using a hydrogen gas, the acceleration voltage is preferably set at greater than or equal to 10 kV and less than or equal to 200 kV, and the dose is preferably set at greater than or equal to 1×10¹⁶ ions/cm² and less than or equal to 6×10¹⁶ ions/cm². By performing ion irradiation in this manner, the embrittlement layer 104 can be formed in a region at a depth greater than or equal to 50 nm and less than or equal to 500 nm, preferably greater than or equal to 50 nm and less than or equal to 200 nm, for example, about 100 nm from the surface of the bond substrate 100, although the depth at which the embrittlement layer 104 is formed also depends on the ion species included in the ion beam and the proportion thereof, or the thickness of the insulating film 102.

Next, the bond substrate 100 over which the insulating film 102 is formed is cleaned. This cleaning step can be performed by ultrasonic cleaning with the use of pure water or by two-fluid jet cleaning with the use of pure water and nitrogen. The ultrasonic cleaning is preferably megahertz ultrasonic cleaning (megasonic cleaning). After the ultrasonic cleaning or the two-fluid jet cleaning, the bond substrate 100 may be cleaned with ozone water. By the cleaning with ozone water, removal of organic substances and surface activation for improving the hydrophilic property of a surface of the insulating film 102 can be performed.

The surface activation of the insulating film 102 can be performed by irradiation with an atomic beam or an ion beam, ultraviolet treatment, ozone treatment, plasma treatment, plasma treatment by application of a bias voltage or radical treatment instead of cleaning with ozone water (this step corresponds to a step A-4 in FIG. 6). When an atomic beam or an ion beam is used, an inert gas neutral atom beam or inert gas ion beam of argon or the like can be used.

Here, an example of ozone treatment will be described. For example, ozone treatment can be performed on a surface of an object by irradiation with ultraviolet (UV) in an atmosphere containing oxygen. Ozone treatment in which irradiation with ultraviolet is performed under an atmosphere containing oxygen is also called UV ozone treatment, ultraviolet ozone treatment, or the like. In an atmosphere containing oxygen, irradiation with light including a wavelength of less than 200 nm and light including a wavelength of greater than or equal to 200 nm among ultraviolet is performed, whereby ozone can be generated and singlet oxygen can be generated by ozone. Irradiation with light including a wavelength of less than 180 nm among ultraviolet is performed, whereby ozone can be generated and singlet oxygen can be generated by ozone.

Examples of reactions which occur by performing irradiation with light including a wavelength of less than 200 nm and light including a wavelength of greater than or equal to 200 nm in an atmosphere containing oxygen are described.

O₂+hv(λ₁ nm)→O(³P)+O(³P) (1)

O(³P)+O₂→O₃ (2)

O₃+hv(λ₂ nm)→O(¹D)+O₂ (3)

In the above reaction formula (1), irradiation with light (hv) including a wavelength (λ₁ nm) of less than 200 nm in an atmosphere containing oxygen (O₂) is performed to generate an oxygen atom (O(³P)) in a ground state. Next, in the reaction formula (2), an oxygen atom (O(³P)) in a ground state and oxygen (O₂) are reacted with each other to generate ozone (O₃). Then, in the reaction formula (3), irradiation with light including a wavelength (λ₂ nm) of greater than or equal to 200 nm in an atmosphere containing generated ozone (O₃) is performed to generate singlet oxygen O(¹D) in an excited state. In an atmosphere containing oxygen, irradiation with light including a wavelength of less than 200 nm among ultraviolet is performed to generate ozone while irradiation with light including a wavelength of greater than or equal to 200 nm among ultraviolet is performed to generate singlet oxygen by decomposing ozone. The ozone treatment as described above, for example, can be performed by irradiation with light of a low-pressure mercury lamp (λ₁=185 nm, λ₂=254 nm) in an atmosphere containing oxygen.

In addition, examples of reactions which occur by performing irradiation with light including a wavelength of less than 180 nm in an atmosphere containing oxygen are described.

O₂+hv(λ₃ nm)→O(¹D)+O(³P) (4)

O(³P)+O₂→O₃ (5)

O₃+hv(λ₃ nm)→O(¹D)+O₂ (6)

In the above reaction formula (4), irradiation with light including a wavelength (λ₃ nm) of less than 180 nm in an atmosphere containing oxygen (O₂) is performed to generate singlet oxygen O(¹D) in an excited state and an oxygen atom (O(³P)) in a ground state. Next, in the reaction formula (5), an oxygen atom (O(³P)) in a ground state and oxygen (O₂) are reacted with each other to generate ozone (O₃). In the reaction formula (6), irradiation with light including a wavelength (λ₃ nm) of less than 180 nm in an atmosphere containing generated ozone (O₃) is performed to generate singlet oxygen in an excited state and oxygen. In an atmosphere containing oxygen, irradiation with light including a wavelength of less than 180 nm among ultraviolet is performed to generate ozone and to generate singlet oxygen by decomposing ozone or oxygen. The ozone treatment as described above, for example, can be performed by irradiation with light of a Xe excimer UV lamp (λ₃=172 nm) in an atmosphere containing oxygen.

Chemical bonding of an organic substance attached to a surface of an object is cut by light including a wavelength of less than 200 nm, whereby the organic substance attached to the surface of the object or the organic substance whose chemical bonding is cut can be removed by oxidative decomposition with ozone or singlet oxygen generated by ozone. By performing ozone treatment as described above, a hydrophilic property and purity of the surface of the object can be increased, and bonding can be favorably performed.

In an atmosphere containing oxygen, ozone is generated by performing irradiation with ultraviolet. Ozone is effective in removal of the organic substance attached to the surface of the object. In addition, singlet oxygen is also effective in removal of the organic substance attached to the surface of the object as much as or more than ozone. Ozone and singlet oxygen are examples of oxygen in an actively state, and collectively called active oxygen. As described with the above reaction formulae and the like, since there are reactions where ozone is generated in generating singlet oxygen or singlet oxygen is generated by ozone, here, such reactions including a reaction where singlet oxygen contributes are called ozone treatment for convenience.

Next, a process of preparing for bonding the glass substrate 120 which is a base substrate to the bond substrate 100 will be described. The following process corresponds to Process B (glass substrate process) in FIG. 6.

First, the glass substrate 120 is prepared (this step corresponds to a step B-1 in FIG. 6). A variety of glass substrates for electronics industry, such as an alumino silicate glass substrate, a barium borosilicate glass substrate, or an aluminoborosilicate glass substrate can be used as the glass substrate 120. As the glass substrate 120, a substrate that has a coefficient of thermal expansion higher than or equal to 25×10⁻⁷/° C. and lower than or equal to 50×10⁻⁷/° C. (preferably higher than or equal to 30×10⁻⁷/° C. and lower than or equal to 40×10⁻⁷/° C.), and a distortion point at higher than or equal to 580° C. and lower than or equal to 680° C. (preferably higher than or equal to 600° C. and lower than or equal to 680° C.) is preferably used. When the glass substrate 120 is an alkali-free glass substrate, impurity contamination of semiconductor devices can be suppressed.

As the glass substrate 120, a mother glass substrate which has been developed for manufacturing liquid crystal panels is preferably used. As such a mother glass substrate, substrates having the following sizes are known: the third generation (550 mm×650 mm), the 3.5-th generation (600 mm×720 mm), the fourth generation (680 mm×880 mm, or 730 mm×920 mm), the fifth generation (1100 mm×1300 mm), the sixth generation (1500 mm×1850 mm), the seventh generation (1870 mm×2200 mm), the eighth generation (2200 mm×2400 mm), the 9th generation (2400 mm×2800 mm), and the 10th generation (2850 mm×3050 mm) and the like. By manufacturing an SOI substrate with the use of a large-sized mother glass substrate as the glass substrate 120, the SOI substrate can have a large area. Increasing the area of the SOI substrate enables many chips such as ICs or LSIs to be manufactured all at once, and thus the number of chips manufactured from one substrate is increased; therefore, productivity can be dramatically increased.

Further, an insulating film 122 is preferably formed over the glass substrate 120 (this step corresponds to a step B-2 in FIG. 6). Note that the insulating film 122 is not necessarily formed on the surface of the glass substrate 120. However, by forming, as the insulating film 122, a silicon nitride film, a silicon nitride oxide film, an aluminum nitride film, an aluminum nitride oxide film, or the like on the surface of the glass substrate 120, impurities such as an alkali metal or an alkaline earth metal in the glass substrate 120 can be prevented from entering the bond substrate 100.

The surface of the glass substrate 120 is cleaned before the bonding. The surface of the glass substrate 120 can be cleaned with chlorine acid and hydrogen peroxide water or by megahertz ultrasonic cleaning, two-fluid jet cleaning, or cleaning with ozone water. Similarly to the insulating film 102, preferably after the surface activation treatment such as irradiation with an atomic beam or an ion beam, ultraviolet treatment, ozone treatment, plasma treatment, plasma treatment by application of a bias voltage or radical treatment is performed, bonding is performed (this step corresponds to a step B-3 in FIG. 6).

Next, a process in which the bond substrate 100 is bonded to the glass substrate 120 and then separated into the semiconductor film 124 bonded to the glass substrate 120 which is to be an SOI substrate and a separated bond substrate 121 which is subjected to reprocessing treatment and reprocessed as a reprocessed bond substrate will be described. The following process corresponds to Process C (bonding process) in FIG. 6.

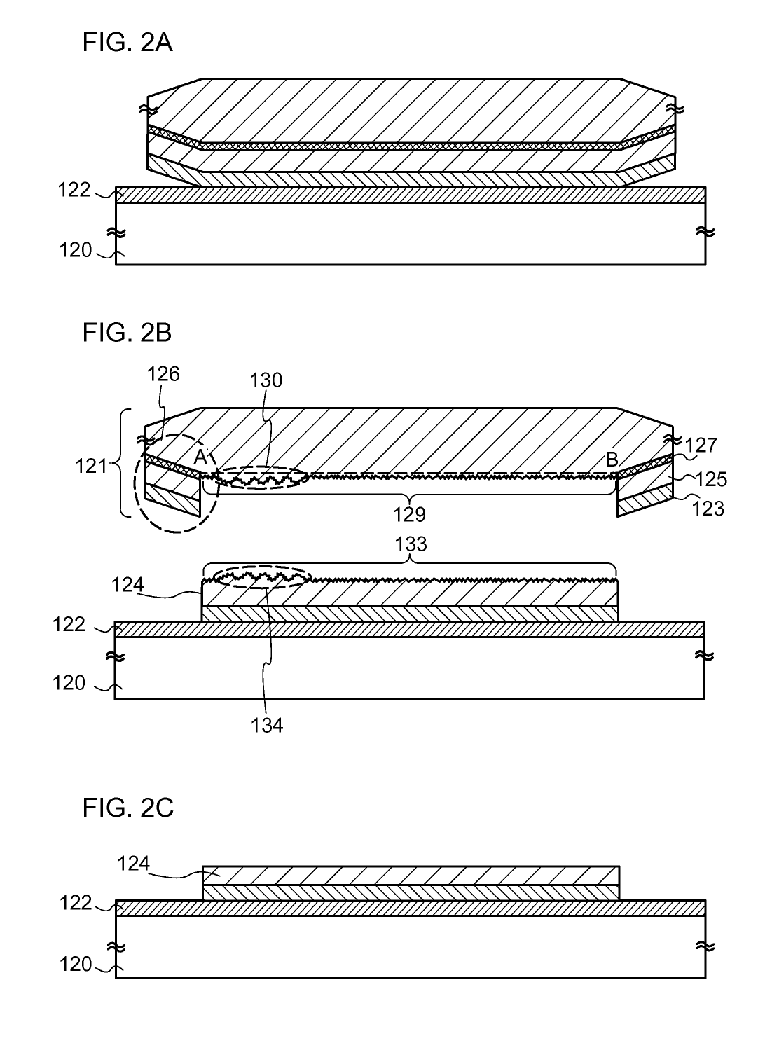

Next, as illustrated in FIG. 2A, the bond substrate 100 and the glass substrate 120 are bonded to each other with the insulating film 102 and the insulating film 122 interposed therebetween so that the insulating film 102 faces the glass substrate 120 side (this step corresponds to a step C-1).

The bonding can be performed by applying pressure of about 1 N/cm² to 500 N/cm², preferably about 1 N/cm² to 20 N/cm² to one part at an end of the glass substrate 120. The bonding between the insulating film 102 and the glass substrate 120 start from the portion of the glass substrate 120 at which the pressure is applied and proceeds spontaneously throughout the surface, and thus one glass substrate 120 and the bond substrate 100 are bonded to each other.

However, as in this embodiment, in the case where there is a chamfer portion in a peripheral portion of the bond substrate 100, the glass substrate 120 and the bond substrate 100 are not in contact with each other in the chamber portion.

When the bond substrate 100 is manufactured, a CMP method or the like is used as finishing polishing. In a CMP method, a slurry (an abrasive) penetrates between the bond substrate 100 and an abrasive cloth and passes between the bond substrate 100 and the abrasive cloth by centrifugal force; thus, the bond substrate 100 is polished. However, when a slurry penetrates a little therebetween at this time, a peripheral portion of the bond substrate 100 is polished faster than the center of the bond substrate 100, so that a region where the substrate has a smaller thickness and has lower planarity than the center, which is referred to as edge roll-off (ERO), is formed. Also in the case where there is no chamfer portion at an end portion of the bond substrate 100, due to the ERO region in the peripheral portion of the bond substrate 100, the glass substrate 120 and the bond substrate 100 cannot be bonded to each other in the peripheral portion of the bond substrate 100 in some cases.

In addition, also in the case where when the bond substrate 100 is transferred, the periphery portion of the bond substrate 100 is damaged by a carrier or the like, the glass substrate 120 and the bond substrate 100 cannot be bonded to each other in the peripheral portion of the bond substrate 100 in some cases.

The bonding is performed by Van der Waals force, so that the bonding is firm even at room temperature. By applying pressure to the bond substrate 100 and the glass substrate 120, the bond substrate 100 and the glass substrate 120 can be firmly bonded to each other by hydrogen bond. Note that since the above-described bonding can be performed at a low temperature, as described above, various substrates can be used for the glass substrate 120.

In the case where a plurality of bond substrates 100 is bonded to the base substrate, there are some cases in which the glass substrate 120 is not in contact with all the surfaces of the insulating films 102 because of the difference in thickness between the bond substrates 100. Therefore, the pressure is preferably applied to not just one point but each bond substrate 100. Even if the surfaces of the insulating films 102 are a little different in height, the bonding can be performed on the entire surfaces of the insulating films 102 as long as a part of the insulating film 102 is in close contact with the glass substrate 120 by bending of the glass substrate 120.

After the bond substrate 100 is bonded to the glass substrate 120, heat treatment for increasing the bonding force at the bonding interface between the glass substrate 120 and the insulating film 102 is preferably performed (this step corresponds to a step C-2 in FIG. 6). This heat treatment is performed at a temperature at which the embrittlement layer 104 does not crack; specifically, the temperature is in the range of higher than or equal to 200° C. and lower than or equal to 450° C. By bonding the bond substrate 100 to the glass substrate 120 by heat treatment within this temperature range, the bonding between the glass substrate 120 and the insulating film 102 can be strengthened. The heat treatment for increasing the bonding force at the bonding interface is preferably performed successively in the apparatus or at the place where the bonding has been performed. In succession to the heat treatment for increasing the bonding force at the bonding interface, another heat treatment for separating the bond substrate 100 along the embrittlement layer 104 may be performed.

Note that when a particle or the like is attached to the bonding surface in bonding the bond substrate 100 and the glass substrate 120, the portion where a particle or the like is attached is not bonded. In order to avoid attachment of a particle to the bonding surface, the bond substrate 100 and the glass substrate 120 are preferably bonded in an airtight treatment chamber. Further, when the bond substrate 100 and the glass substrate 120 are bonded to each other, it is preferable that the treatment chamber be in a state with a reduced pressure of approximately 5.0×10⁻³ Pa and an atmosphere in which bonding treatment is performed be cleaned.

Next, as illustrated in FIG. 2B, by heat treatment, micorvoids adjacent to each other in the embrittlement layer 104 are combined, so that the microvoids increase in volume. As a result, through an explosive reaction at the embrittlement layer 104, the semiconductor film 124 is separated from the bond substrate 100 (this step corresponds to a step C-3 in FIG. 6). Since the insulating film 102 is bonded to the glass substrate 120, the semiconductor film 124 separated from the bond substrate 100 is fixed to the glass substrate 120. The heat treatment for separating the semiconductor film 124 from the bond substrate 100 is performed at a temperature below the strain point of the glass substrate 120.

For the heating treatment, an RTA (rapid thermal anneal) apparatus, a resistance heating furnace, or a microwave heating apparatus can be used. As an RTA apparatus, a GRTA (gas rapid thermal anneal) apparatus or an LRTA (lamp rapid thermal anneal) apparatus can be used.

In the case of using a GRTA apparatus, the heating temperature can be in the range of from 550° C. to 650° C., and the treatment time can be in the range of 0.5 minutes to 60 minutes. In the case of using a resistance heating apparatus, the heating temperature can be in the range of 200° C. to 650° C., and the treatment time can be in the range of 2 hours to 4 hours.

The heat treatment may be performed by dielectric heating with a high-frequency wave such as a microwave. The heat treatment by dielectric heating can be performed by irradiating the bond substrate 100 with a high-frequency wave with a frequency of 300 MHz to 3 THz generated by a high-frequency wave generating apparatus. In specific, for example, irradiation with a microwave with a frequency of 2.45 GHz is performed at 900 W for 14 minutes to expand microvoids and combine the microvoids adjacent to each other in the embrittlement layer, whereby the bond substrate 100 can be separated at last.

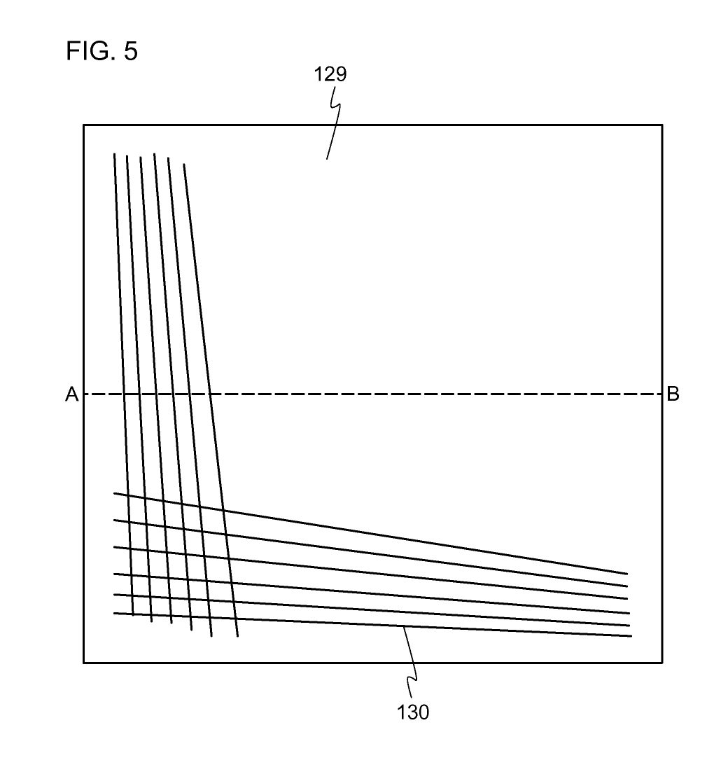

However, many crystal defects are formed on the surface of the separated bond substrate 121 from which the semiconductor film 124 of a thin film has been separated by heat treatment, and the planarity of the separated bond substrate 121 is damaged severely. In particular, when the bond substrate 100 formed using a semiconductor and the glass substrate 120 of which coefficient of thermal expansion is different from that of the bond substrate 100 are bonded to each other and the semiconductor film 124 is separated from the bond substrate 100, a thickness non-uniformity 134 is formed on a separation surface 133 of the semiconductor film 124, and a thickness non-uniformity 130 is formed on a separation surface 129 of the separated bond substrate 121 obtained by separating the semiconductor film 124 from the bond substrate 100. As the separation surface 129 and the separation surface 133 are exposed at the time of separation of the bond substrate 100, the thickness non-uniformity 130 and the thickness non-uniformity 134 are formed step by step. The thickness non-uniformity 130 and the thickness non-uniformity 134 have a thickness of about 10 nm to 100 nm. For example, in the case of the rectangular separated bond substrate 121, as illustrated in FIG. 5, the thickness non-uniformity 130 having an L shape or a reversed C shape is formed. FIG. 5 is a plan view of the separation surface 129 of the separated bond substrate 121 of FIG. 2B. A dashed line A-B of FIG. 5 corresponds to a dashed line A-B of FIG. 2B.

The peripheral portion of the bond substrate 100 is not bonded to the glass substrate 120 in many cases due to the chamfer portion, the ERO region, a damage formed at the time of transfer of the bond substrate 100, or the like. When the semiconductor film 124 is separated from the bond substrate 100 in such a state, the peripheral portion of the bond substrate 100 which is not bonded to the glass substrate 120 remains on the bond substrate 100, and thus a projection 126 is formed at the periphery of the separated bond substrate 121. The projection 126 includes a remaining embrittlement layer 127, a remaining semiconductor layer 125, and a remaining insulating film 123. The semiconductor film 124 which is smaller than the bond substrate 100 is bonded to the glass substrate 120.

Next, a process of planarizing the surface of the semiconductor film 124 which is bonded to the glass substrate 120 to recover crystallinity will be described. The following process corresponds to Process D (finishing process of an SOI substrate) in FIG. 6.

Next, as illustrated in FIG. 2C, the surface of the semiconductor film 124 may be planarized by polishing (this step corresponds to a step D-1 in FIG. 6). Although not necessarily essential, the planarization makes it possible to improve characteristics of the interface between the semiconductor film and a gate insulating film that is to be formed later. Specifically, the polishing may be chemical mechanical polishing (CMP), liquid jet polishing, or the like. The thickness of the semiconductor film 124 is reduced by the above planarization.

Also, the surface of the semiconductor film 124 can be planarized by being etched. The etching may be performed using a dry etching method, for example, reactive ion etching (RIE), ICP (Inductively Coupled Plasma) etching, ECR (Electron Cyclotron Resonance) etching, parallel plate (Capacitive Coupled Plasma) etching, magnetron plasma etching, dual-frequency plasma etching, helicon wave plasma etching, or the like. Note that using both the above polishing and the above etching, the surface of the semiconductor film 124 may be planarized.

The etching can not only thin the semiconductor film 124 to the thickness optimum for a semiconductor element which is to be formed later but also planarize the surface of the semiconductor film 124. Further, the etching can remove the thickness non-uniformity 134 formed on the separation surface 133.

Note that in the semiconductor film 124 bonded to the glass substrate 120, crystal defects are formed due to the formation of the embrittlement layer 104 and the separation at the embrittlement layer 104, and thus planarity of the surface of the semiconductor film 124 is damaged. Laser irradiation may be performed on the semiconductor film 124 in order to reduce the crystal defects and improve the planarity (this step corresponds to a step D-2 in FIG. 6).

In the case where the surface of the semiconductor film 124 is planarized by dry etching before the laser irradiation, damages such as crystal defects might occur at the surface of the semiconductor film 124 due to the dry etching. However, the laser irradiation can also repair the damages caused by the dry etching.

Since an increase in the temperature of the glass substrate 120 can be suppressed in this laser irradiation step, a substrate having low heat resistance can be used as the glass substrate 120. It is preferable that the semiconductor film 124 be partly melted by the laser irradiation. This is because if the semiconductor film 124 is completely melted, the recrystallization of the semiconductor film 124 is accompanied with disordered nucleation of the semiconductor film 124 in a liquid phase and crystallinity of the semiconductor film 124 is lowered. By partial melting, so-called longitudinal growth in which crystal growth proceeds from an unmelted solid portion occurs in the semiconductor film 124. Due to the recrystallization by the longitudinal growth, crystal defects of the semiconductor film 124 are decreased and crystallinity thereof is recovered. The state in which the semiconductor film 124 is completely melted means the state in which the semiconductor film 124 is melted to be in a liquid state to the interface with the insulating film 102. On the other hand, the state where the semiconductor layer 124 is partly melted means that an upper part thereof is melted and is in a liquid phase and a lower part thereof is in a solid phase.

Next, after the laser irradiation, the surface of the semiconductor film 124 may be etched. If the surface of the semiconductor film 124 is etched after the laser irradiation, the surface of the semiconductor film 124 is not necessarily etched before the laser irradiation. Moreover, if the surface of the semiconductor film 124 is etched before the laser irradiation, the surface of the semiconductor film 124 is not necessarily etched after the laser irradiation. Alternatively, the etching may be performed both before and after the laser irradiation.

The etching can not only thin the semiconductor film 124 to the thickness optimum for a semiconductor element which is to be formed later but also planarize the surface of the semiconductor film 124.

After the laser irradiation, the semiconductor film 124 is preferably subjected to heat treatment at higher than or equal to 500° C. and lower than or equal to 650° C. (this step corresponds to a step D-3 in FIG. 6). By this heat treatment, the defects of the semiconductor film 124 which are not repaired by the laser irradiation can be eliminated and distortion of the semiconductor film 124 can be alleviated. For the heating treatment, an RTA (rapid thermal anneal) apparatus, a resistance heating furnace, or a microwave heating apparatus can be used. As an RTA apparatus, a GRTA (gas rapid thermal anneal) apparatus or an LRTA (lamp rapid thermal anneal) apparatus can be used. For example, when a resistance heating furnace is used, heat treatment is preferably performed at 600° C. for about 4 hours.

An SOI substrate manufactured in this manner is processed into a semiconductor device through a process F (a device process) which will be described in Embodiment 2.

The SOI substrate described in this embodiment can be used in manufacturing any kind of semiconductor devices including microprocessors, integrated circuits such as image processing circuits, RF tags for transmitting and receiving data with an interrogator without contact, semiconductor display devices, and the like. The semiconductor display devices include the following in its category: liquid crystal display devices, light-emitting devices in which a light-emitting element typified by an organic light-emitting element (OLED) is provided for each pixel, DMDs (digital micromirror devices), PDPs (plasma display panels), FEDs (field emission displays), and other semiconductor display devices in which a circuit element using a semiconductor film is included in a driver circuit.

Next, a process of performing reprocessing treatment on the separated bond substrate 121 to repeatedly use the separated bond substrate 121 as a reprocessed bond substrate will be described. The following process corresponds to Process E (bond substrate reprocessing treatment process) in FIG. 6.

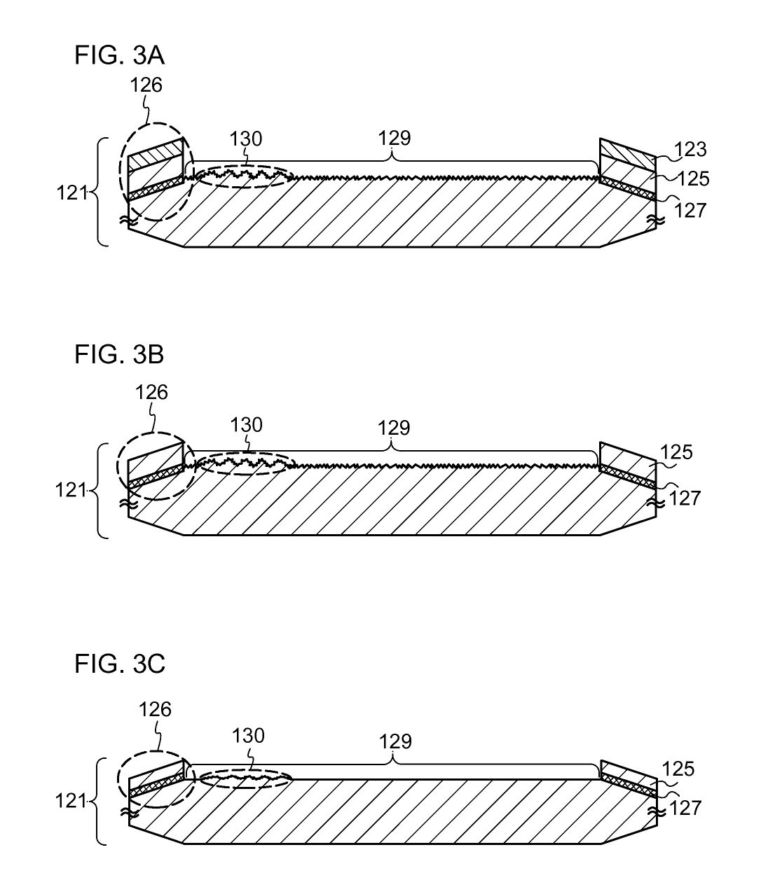

First, the separated bond substrate 121 illustrated in FIG. 3A is taken out. The projection 126 is formed at the periphery of the separated bond substrate 121. The projection 126 includes the remaining embrittlement layer 127, the remaining semiconductor layer 125, and the remaining insulating film 123 in order from the semiconductor substrate side. On the separation surface 129 of the separated bond substrate 121, crystal defects are formed, the planarity is damaged, and the thickness non-uniformity 130 is formed. Further, the separated bond substrate 121 is damaged to a depth of 300 nm to 700 nm, for example, 500 nm from an upper surface of the remaining semiconductor layer 125, due to the hydrogen ion irradiation for forming the embrittlement layer.

Next, as illustrated in FIG. 3B, the remaining insulating film 123 included in the projection 126 is removed (this step corresponds to a step E-1 in FIG. 6). The remaining insulating film 123 can be removed by wet etching treatment using a solution containing hydrofluoric acid as an etchant. As a solution containing hydrofluoric acid, a mixed solution containing hydrofluoric acid, ammonium fluoride, and a surfactant (e.g. manufactured by Stella Chemifa Corporation, product name: LAL 500) is preferably used. This wet etching is preferably performed for 120 seconds to 1200 seconds, for example, 600 seconds. Further, the wet etching is performed in such a manner that the separated bond substrate 121 is soaked in a solution in a treatment tank; therefore, a plurality of the separated bond substrates 121 can be processed collectively. The remaining insulating film 123 is removed by wet etching, whereby a polishing step with a high polishing rate by a CMP method to be performed in a later step can be omitted, a polishing rate can be lowered, and the polishing time can be shortened.

Next, as illustrated in FIG. 3C, a difference in height between the thickness non-uniformity 130 of the separation surface 129 and the remaining semiconductor layer 125 of the projection 126 is reduced (this step corresponds to a step E-2 in FIG. 6). The thickness non-uniformity 130 and the remaining semiconductor layer 125 are subjected to wet etching treatment using an organic alkaline aqueous solution as an etchant, whereby the difference in height can be reduced. As an organic alkaline aqueous solution, a solution containing tetramethylammonium hydroxide (TMAH) by 0.2% to 5.0% (e.g. product name: NMD3, manufactured by Tokyo Ohka Kogyo Co., Ltd) is preferably used. The temperature of the organic alkaline aqueous solution is preferably 40° C. to 70° C., for example, about 50° C. This wet etching is preferably performed for 30 seconds to 600 seconds, for example, about 60 seconds. Note that when wet etching takes much time, asperity of the surface of the separated bond substrate 121 including the remaining semiconductor layer 125 becomes large. Further, the wet etching is performed in such a manner that the separated bond substrate 121 is soaked in a solution in a treatment tank; therefore, a plurality of the separated bond substrates 121 can be processed collectively.

By this wet etching, the thickness non-uniformity 130 can be significantly reduced. At the same time, a semiconductor layer having crystal defects formed on the separation surface 129 can be removed. The difference in height due to the remaining semiconductor layer 125 can be reduced to about 10 nm to 70 nm. The thickness non-uniformity 130 is reduced, the crystal defects formed on the separation surface 129 are removed, and the difference in height due to the remaining semiconductor layer 125 is reduced, whereby a polishing step with a high polishing rate by a CMP method which is to be performed in a later step can be omitted, a polishing rate can be lowered, and polishing time can be shortened.

In addition, a side surface of the separated bond substrate 121 is also subjected to wet etching, whereby damages of the side surface which are caused in transferring the separated bond substrate 121 can be removed. When reprocessing treatment is performed on the separated bond substrate 121 in which damages of the side surface are remaining and heat treatment is again performed on the separated bond substrate 121 as a bond substrate, slip dislocation or a crack is easily generated around the damage of the side surface.

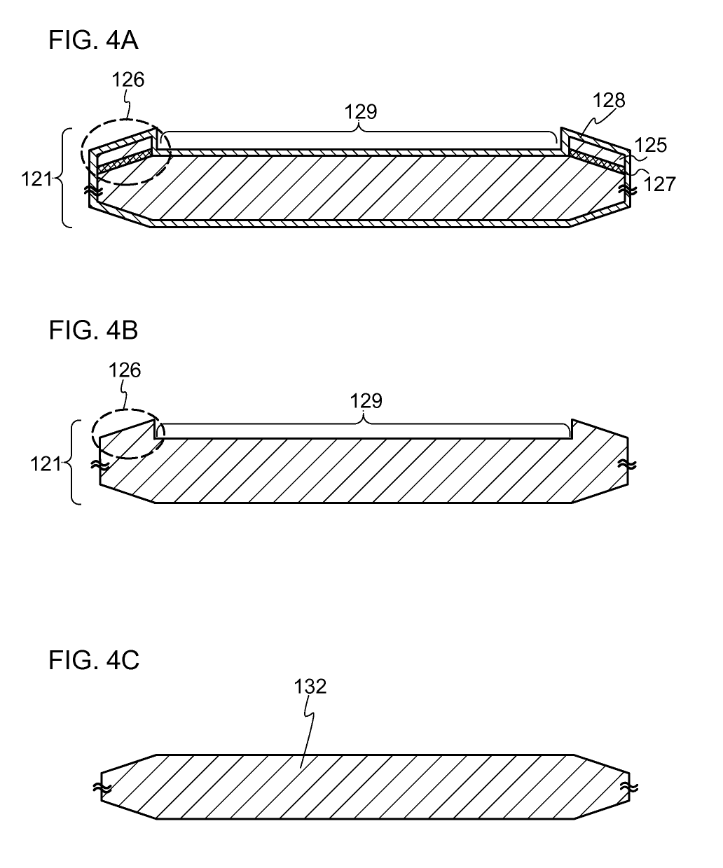

Next, as illustrated in FIG. 4A, thermal oxidation is performed on the separated bond substrate 121 in an oxidizing atmosphere to which a gas containing halogen is added to form an oxide film 128 (this step corresponds to a step E-3 in FIG. 6). As a gas containing halogen, HCl is preferably used. By thermal oxidation treatment in the oxidizing atmosphere containing halogen, the oxide film 128 can be made to contain halogen. The oxide film 128 is made to contain halogen, whereby the oxide film 128 captures a heavy metal which is an extrinsic impurity (e.g. Fe, Cr, Ni, or Mo) or movable ions (e.g. Na); therefore, the oxide film 128 is removed in a later step, whereby a heavy metal or movable ions can be removed from the separated bond substrate 121. Note that in an oxidizing atmosphere, the volume of oxygen is preferably about 100 volume %, and in the oxidizing atmosphere containing halogen, the total volume of oxygen and halogen is preferably about 100 volume %.

In this embodiment, the oxide film 128 is formed using HCl. At this time, the oxide film 128 is preferably formed in an atmosphere that contains HCl at 0.5 volume % to 10 volume % (e.g. 3 volume %) with respect to oxygen. Further, heat treatment is preferably performed at a temperature of 700° C. to 1100° C. for 0.1 hours to 6 hours, for example, at 950° C. for 2.5 hours to 3 hours. A thermal oxide film formed at this time can have a thickness of 15 nm to 1100 nm, preferably 50 nm to 150 nm, for example, 90 nm. Further, in thermal oxidation, the plurality of separated bond substrates 121 can be easily processed collectively.

The oxide film 128 is formed on the separated bond substrate 121 in an oxidizing atmosphere containing HCl, whereby the thickness non-uniformity 130 on the separation surface 129 is not observed on the oxide film 128. At the same time, the separated bond substrate 121 which is contaminated with hydrogen ions to a depth of about 500 nm from an upper surface of the remaining semiconductor layer 125 can be dehydrogenated. At this time, the remaining embrittlement layer 127 in which many hydrogen ions are especially contained is also dehydrogenated. By dehydrogenation of the separated bond substrate 121, a polishing step with a high polishing rate by a CMP method which is to be performed in a later step can be omitted, a polishing rate can be lowered, and polishing time can be shortened. Further, the oxide film 128 is formed in the oxidizing atmosphere containing HCl, whereby a gettering effect obtained by a Cl atom can be obtained. In particular, the gettering has an effect of removing a metal impurity or the like. In other words, since impurities such as a metal can be captured by action of a Cl atom and fixed in the oxide film 128, by removing the oxide film 128 later, a metal impurity can be removed from the separated bond substrate 121. Further, a Cl atom which captures impurities such as a metal turns into volatile chloride, and then is released into air and removed from the separated bond substrate 121 in some cases.

Next, as illustrated in FIG. 4B, the oxide film 128 is removed (this step corresponds to a step E-4 in FIG. 6). The oxide film 128 is removed in a manner similar to the remaining insulating film 123, and as an etchant, a solution containing hydrofluoric acid, preferably, a mixture containing hydrofluoric acid, ammonium fluoride, and a surfactant (e.g., product name: LAL 500 manufactured by STELLA CHEMIFA CORPORATION), is used. This wet etching is also preferably performed for 120 seconds to 1200 seconds, for example, about 600 seconds. Further, the wet etching is performed in such a manner that the separated bond substrate 121 is soaked in a solution in a treatment tank; therefore, the plurality of separated bond substrates 121 can be processed collectively. At this time, the thickness non-uniformity 130 formed on the separation surface 129 is removed completely. Note that in this embodiment, before formation of the oxide film 128, wet etching with an organic alkaline aqueous solution is performed; however, this embodiment is not limited thereto. After the formation of the oxide film 128 and wet etching, wet etching with an organic alkaline aqueous solution may be performed.

Next, as illustrated in FIG. 4C, polishing is performed on the separated bond substrate 121 to form a reprocessed bond substrate 132 (this step corresponds to a step E-5 in FIG. 6). As a polishing method, a chemical mechanical polishing (CMP) method is preferably performed. Here, a CMP method is a method in which a surface of an object to be processed is planarized by a chemical and mechanical compound effect. In general, the CMP method is a method in which a polishing cloth is attached to a polishing stage, the polishing stage and the object to be processed are each rotated or swung while a slurry (an abrasive) is supplied between the object to be processed and the polishing cloth, and the surface of the object to be processed is polished by chemical reaction between the slurry and the surface of the object to be processed and by action of mechanical polishing of the object to be processed with the polishing cloth. In this embodiment, a CMP method is preferably performed with a low polishing rate. At this time, a suede polishing cloth is preferably used, the grain diameter of the slurry is preferably 30 nm to 90 nm, for example, about 60 nm. In this manner, polishing is performed on the separated bond substrate 121, whereby the reprocessed bond substrate 132 which is planarized and made to have a mirror surface can be formed such that the average surface roughness is about 0.2 nm to 0.5 nm and the polished portion is about 200 nm to 1000 nm.

Through the above steps, by wet etching, the thickness non-uniformity 130 and the remaining insulating film 123 are removed, the difference in height due to the remaining semiconductor layer 125 is reduced, and hydrogen ions in the bond substrate including the remaining embrittlement layer 127 are removed by thermal oxidation. Therefore, polishing with a high polishing rate can be omitted and the surface of the separated bond substrate 121 can be sufficiently planarized and made to have a mirror surface simply by polishing with a low polishing rate. Using a CMP method, a polishing step with a high polishing rate is omitted, and a polishing step with a low polishing rate is performed, whereby a polished portion required for planarization and to make a mirror surface of the separated bond substrate 121 can be reduced. Therefore, a removed portion of a bond substrate in one reprocessing treatment can be reduced, and thus the number of times of reusing one bond substrate can be increased, which greatly contributes to a reduction in cost of manufacturing an SOI substrate.

Further, in a CMP method, a slurry penetrates between an object to be processed and a polishing cloth and passes between the object to be processed and the polishing cloth by centrifugal force, whereby the object to be processed is polished. However, when a slurry penetrates a little therebetween at this time, a peripheral portion of the object to be processed is polished faster than the center of the object to be processed, so that a region where the thickness of the substrate is smaller and which has lower planarity than the center, which is referred to as edge roll-off (E.R.O), is formed in the periphery of the object which is to be processed. As the polishing rate is higher and the polishing time is longer, the area of an ERO region becomes larger; therefore, a polishing step with a high polishing rate is omitted and a polishing step with low polishing rate is performed, whereby the ERO region can be small.

Further, the above wet etching treatment and thermal oxidation treatment in an oxidizing atmosphere containing HCl are batch type treatments in which the plurality of separated bond substrates 121 are processed collectively, which can be easily performed. However, a polishing step by a CMP method can be performed only by single-wafer type treatment in which the plurality of separated bond substrates 121 is processed one by one. Therefore, after the wet etching treatment and thermal oxidation treatment with HCl, a CMP method is used, whereby the proportion of the polishing step by a CMP method in the reprocessing treatment is reduced, and thus improvement in throughput of the reprocessing treatment of the separated bond substrate 121 can be expected. At the same time, waste of consumable products such as a slurry and a polishing cloth used in a CMP method is suppressed, and thus a cost can be reduced.

Through the above steps, the separated bond substrate 121 is reprocessed into the reprocessed bond substrate 132. The obtained reprocessed bond substrate 132 is reused as the bond substrate 100 in the process A.

As described in this embodiment, by repeatedly using a bond substrate by reprocessing treatment of the bond substrate, cost reduction can be achieved. The thickness non-uniformity on the surface of the separated bond substrate, which is generated in the case of using a glass substrate as a base substrate, can be removed by two kinds of wet etching, formation of a thermal oxide film in an atmosphere containing halogen, and removal of the thermal oxide film. In this manner, the separated bond substrate can be reused as a reprocessed bond substrate which can be used for manufacture of an SOI substrate. In particular, a reprocessing treatment of the bond substrate which is described in this embodiment is performed, whereby a polishing step with high polishing rate by a CMP method can be omitted, only a polishing step with low polishing rate can be performed, and the polishing time can be shortened; therefore, the thickness non-uniformity of the surface of the separated bond substrate can be removed, and at the same time, a removed portion of the bond substrate can be reduced. Accordingly, a reprocessed bond substrate which can be used for manufacture of an SOI substrate can be reprocessed at low cost.

### Embodiment 2

In this embodiment, a method for manufacturing a semiconductor device by using the SOI substrate manufactured according to the above embodiment will be described. Note that a process described in this embodiment corresponds to a process F (a device process) in FIG. 6.

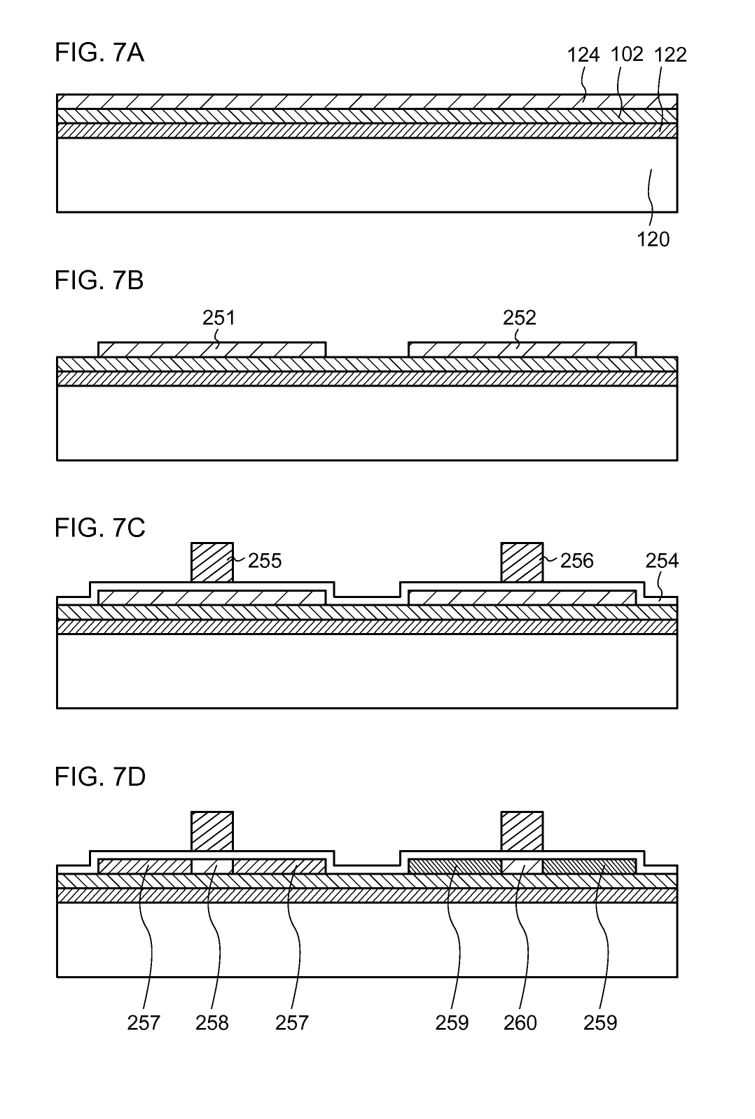

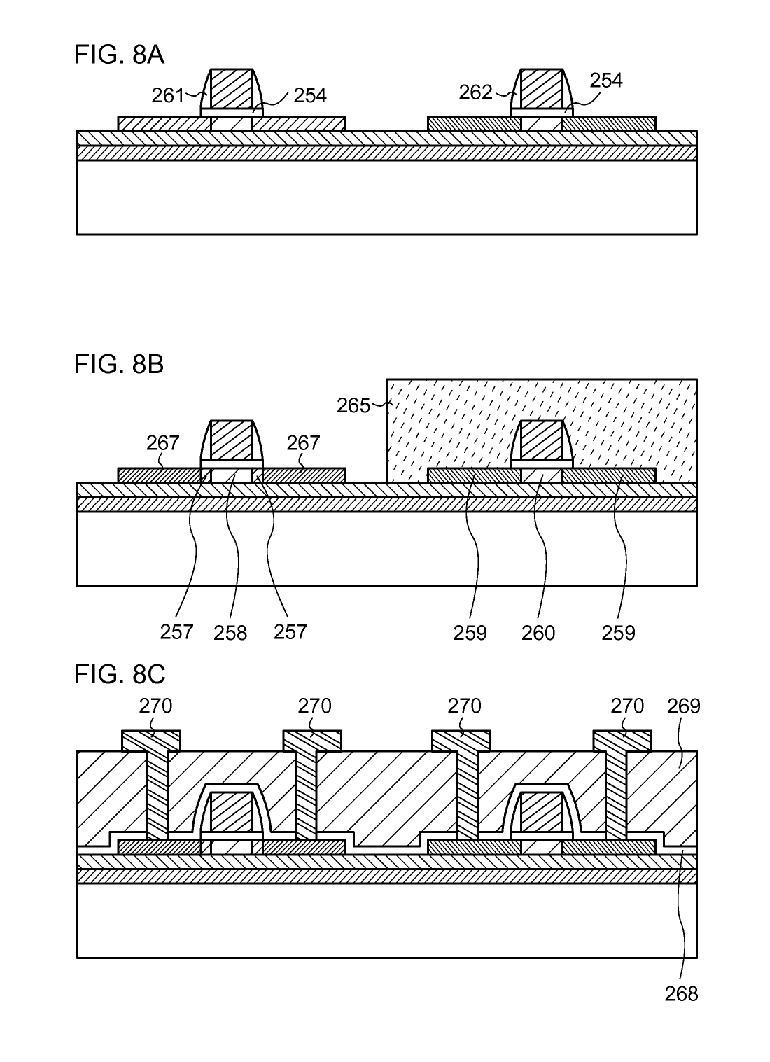

First, with reference to FIGS. 7A to 7D and FIGS. 8A to 8C, a method for manufacturing an n-channel thin film transistor and a p-channel thin film transistor will be described. Various kinds of semiconductor devices can be formed by combining a plurality of thin film transistors (TFTs).

The case where the SOI substrate manufactured by the method of Embodiment 1 is used as an SOI substrate will be described. FIG. 7A is a cross-sectional view of the SOI substrate in FIG. 2C.

The semiconductor film 124 is separated into each element by etching to form a semiconductor film 251 and a semiconductor film 252 as illustrated in FIG. 7B. The semiconductor film 251 is included in an n-channel TFT, and the semiconductor film 252 is included in a p-channel TFT.

As illustrated in FIG. 7C, an insulating film 254 is formed over the semiconductor film 251 and the semiconductor film 252. Then, a gate electrode 255 is formed over the semiconductor film 251 with the insulating film 254 interposed therebetween, and a gate electrode 256 is formed over the semiconductor film 252 with the insulating film 254 interposed therebetween.

Before the semiconductor film 124 is etched, an impurity element which serves as an acceptor, such as boron, aluminum, or gallium, or an impurity element which serves as a donor, such as phosphorus or arsenic, is preferably added into the semiconductor film 124 in order to control the threshold voltage of the TFTs. For example, an impurity element which serves as an acceptor is added into a region where an n-channel TFT is to be formed, and an impurity element which serves as a donor is added to a region where a p-channel TFT is to be formed.

Next, as illustrated in FIG. 7D, n-type low-concentration impurity regions 257 are formed in the semiconductor film 251, and p-type high-concentration impurity regions 259 are formed in the semiconductor film 252. Specifically, first, the n-type low-concentration impurity regions 257 are formed in the semiconductor film 251. For this purpose, the semiconductor film 252 where the p-channel TFT is formed is covered with a resist mask, and an impurity element is added into the semiconductor film 251. As an impurity element, phosphorus or arsenic may be added. When an impurity element is added by an ion doping method or an ion implantation method, the gate electrode 255 serves as a mask, and the n-type low-concentration impurity regions 257 are formed in the semiconductor film 251 in a self-aligned manner. A region of the semiconductor film 251 which overlaps with the gate electrode 255 serves as a channel formation region 258.

Next, after the mask which covers the semiconductor film 252 is removed, the semiconductor film 251 where the n-channel TFT is formed is covered with a resist mask. Next, an impurity element is added into the semiconductor film 252 by an ion doping method or an ion implantation method. As the impurity element, boron, aluminum, gallium, or the like can be added. At the step of adding an impurity element, the gate electrode 256 serves as a mask and the p-type high-concentration impurity regions 259 are formed in the semiconductor film 252 in a self-aligned manner. The p-type high-concentration impurity regions 259 serve as a source region and a drain region. A region of the semiconductor film 252 which overlaps with the gate electrode 256 serves as a channel formation region 260. Here, the method in which the p-type high-concentration impurity regions 259 are formed after the n-type low-concentration impurity regions 257 are formed is described; however, the p-type high-concentration impurity regions 259 can be formed first.

Next, after the resist which covers the semiconductor film 251 is removed, an insulating film having a single layer structure of a nitrogen compound such as silicon nitride or an oxide such as silicon oxide or a stacked layer structure thereof is formed by a plasma CVD method or the like. This insulating film is anisotropically etched in a perpendicular direction to form sidewall insulating films 261 and 262 which are in contact with side surfaces of the gate electrodes 255 and 256, respectively as illustrated in FIG. 8A. By this anisotropic etching, the insulating film 254 is also etched.

Next, as illustrated in FIG. 8B, the semiconductor film 252 is covered with a resist 265. In order to form high-concentration impurity regions serving as a source region and a drain region in the semiconductor film 251, an impurity element is added into the semiconductor film 251 at high dose by an ion implantation method or an ion doping method. The gate electrode 255 and the sidewall insulating film 261 serve as masks, and n-type high-concentration impurity regions 267 are formed. Next, heat treatment for activation of the impurity elements is performed.

After the heat treatment for activation, an insulating film 268 containing hydrogen is formed as illustrated in FIG. 8C. After the insulating film 268 is formed, heat treatment is performed at a temperature of higher than or equal to 350° C. and lower than or equal to 450° C., hydrogen contained in the insulating film 268 is diffused into the semiconductor films 251 and 252. The insulating film 268 can be formed by deposition of silicon nitride or silicon nitride oxide by a plasma CVD method at a process temperature of lower than or equal to 350° C. The supply of hydrogen to the semiconductor films 251 and 252 makes it possible to efficiently compensate defects which are to be trapping centers in the semiconductor films 251 and 252 and at an interface with the insulating film 254.

After that, an interlayer insulating film 269 is formed. The interlayer insulating film 269 can be formed of a film having a single layer structure or a stacked layer structure of any one or more of films selected from an insulating film containing an inorganic material, such as a silicon oxide film or a BPSG (borophosphosilicate glass) film, and an organic resin film containing polyimide, acrylic, or the like. After contact holes are formed in the interlayer insulating film 269, wirings 270 are formed as illustrated in FIG. 8C. The wirings 270 can be formed of a conductive film having a three-layer structure in which a low-resistance metal film such as an aluminum film or an aluminum-alloy film is sandwiched between barrier metal films. The barrier metal films can be formed using metal films which include molybdenum, chromium, titanium, and/or the like.

Through the above steps, a semiconductor device having the n-channel TFT and the p-channel TFT can be manufactured. In a manufacturing process of an SOI substrate used for the semiconductor device of this embodiment, reprocessing treatment of the separated bond substrate is performed and a plurality of semiconductor films are formed using one bond substrate; therefore, a reduction in manufacturing cost and improvement in productivity can be achieved.

Although the method of manufacturing a TFT is described with reference to FIGS. 7A to 7D and FIGS. 8A to 8C, a semiconductor device with high added value can be manufactured by forming a variety of semiconductor elements such as a capacitor and a resistor together with the TFT.

Note that a structure described in this embodiment can be combined with a structure described in other embodiments as appropriate.

### Embodiment 3

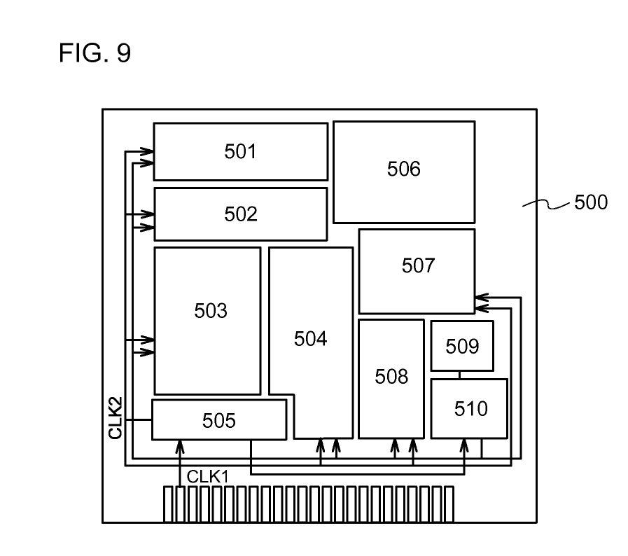

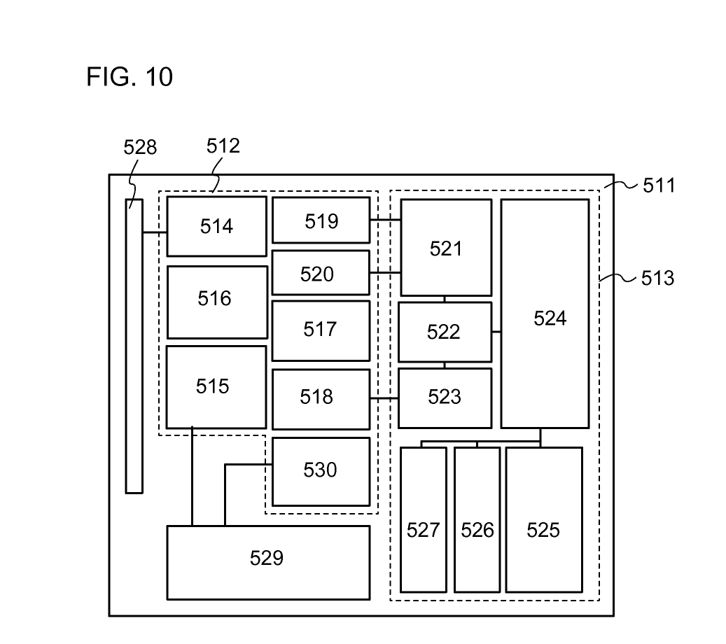

In this embodiment, specific modes of a semiconductor device manufactured by using an SOI substrate described in the above embodiment will be described with reference to FIG. 9 and FIG. 10.

First, a microprocessor will be described as an example of a semiconductor device. FIG. 9 is a block diagram illustrating a structural example of a microprocessor 500.

The microprocessor 500 has an arithmetic logic unit (also referred to as an ALU) 501, an ALU controller 502, an instruction decoder 503, an interrupt controller 504, a timing controller 505, a register 506, a register controller 507, a bus interface (Bus I/F) 508, a read only memory (ROM) 509, and a ROM interface 510.

An instruction input to the microprocessor 500 via the bus interface 508 is input to the instruction decoder 503 and decoded. Then, the instruction is input to the ALU controller 502, the interrupt controller 504, the register controller 507, and the timing controller 505. The ALU controller 502, the interrupt controller 504, the register controller 507, and the timing controller 505 perform various controls based on the decoded instruction.

The ALU controller 502 generates a signal for controlling the operation of the arithmetic logic unit 501. While the microprocessor 500 is executing a program, the interrupt controller 504 judges an interrupt request from an external input and output device or a peripheral circuit based on its priority or a mask state, and processes the interrupt request. The register controller 507 generates an address of the register 506, and reads and writes data from and to the register 506 in accordance with the state of the microprocessor 500. The timing controller 505 generates signals for controlling timing of driving of the arithmetic logic unit 501, the ALU controller 502, the instruction decoder 503, the interrupt controller 504, and the register controller 507. For example, the timing controller 505 is provided with an internal clock generator for generating an internal clock signal CLK2 based on a reference clock signal CLK1. As illustrated in FIG. 9, the internal clock signal CLK2 is input to another circuit.

Next, an example of a semiconductor device having a function of communicating data wirelessly and also having an arithmetic function will be described. FIG. 10 is a block diagram illustrating a structural example of such a semiconductor device. The semiconductor device illustrated in FIG. 10 can be referred to as a computer (hereinafter referred to as an “RFCPU”) which operates to transmit and receive signals to and from an external device by wireless communication.

As illustrated in FIG. 10, an RFCPU 511 has an analog circuit portion 512 and a digital circuit portion 513. The analog circuit portion 512 includes a resonance circuit 514 having a resonant capacitor, a rectifier circuit 515, a constant voltage circuit 516, a reset circuit 517, an oscillator circuit 518, a demodulation circuit 519, a modulation circuit 520, and a power supply management circuit 530. The digital circuit portion 513 includes an RF interface 521, a control register 522, a clock controller 523, a CPU interface 524, a central processing unit (CPU) 525, a random access memory (RAM) 526, and a read only memory (ROM) 527.

The operation of the RFCPU 511 is roughly described below. Induced electromotive force is generated by the resonance circuit 514 based on a signal received at an antenna 528. The induced electromotive force is stored in a capacitor portion 529 via the rectifier circuit 515. The capacitor portion 529 is preferably formed using a capacitor such as a ceramic capacitor or an electric double layer capacitor. The capacitor portion 529 is not necessarily integrated over the same substrate as the RFCPU 511 and may be incorporated into the RFCPU 511 as a component.

The reset circuit 517 generates a signal which resets the digital circuit portion 513 to be initialized. For example, a signal which rises after an increase in a power supply voltage is generated as the reset signal. The oscillator circuit 518 changes the frequency and the duty ratio of a clock signal in accordance with a control signal generated by the constant voltage circuit 516. The demodulation circuit 519 demodulates a received signal, and the modulation circuit 520 modulates data to be transmitted.

For example, the demodulation circuit 519 is formed using a low-pass filter and binarizes a received signal of an amplitude shift keying (ASK) system based on variation of the amplitude. The modulation circuit 520 transmits transmission data by changing the amplitude of a transmission signal of the amplitude shift keying (ASK) system. The modulation circuit 520 changes the resonance point of the resonance circuit 514, whereby the amplitude of a communication signal is changed.

The clock controller 523 generates a control signal for changing the frequency and the duty ratio of the clock signal in accordance with the power supply voltage or current consumption in the central processing unit (CPU) 525. The power supply voltage is monitored by the power supply management circuit 530.

A signal which is input into the RFCPU 511 from the antenna 528 is demodulated by the demodulation circuit 519, and then divided into a control command, data, and the like by the RF interface 521. The control command is stored in the control register 522. The control command includes reading of data stored in the read only memory (ROM) 527, writing of data to the random access memory (RAM) 526, an arithmetic instruction to the central processing unit (CPU) 525, and the like.

The central processing unit (CPU) 525 accesses the read only memory (ROM) 527, the random access memory (RAM) 526, and the control register 522 via the CPU interface 524. The CPU interface 524 has a function of generating an access signal for any one of the read only memory (ROM) 527, the random access memory (RAM) 526, and the control register 522 based on an address requested by the central processing unit (CPU) 525.

As an arithmetic method of the central processing unit (CPU) 525, a method can be employed in which the read only memory (ROM) 527 stores an operating system (OS) and a program is read at the time of starting operation and then is executed. Alternatively, a method can be employed in which a circuit dedicated to arithmetic is formed as an arithmetic circuit and an arithmetic processing is conducted using hardware. In a method in which both hardware and software are used, part of arithmetic processing can be conducted by a circuit dedicated to arithmetic, and the other part of the arithmetic processing can be conducted by the central processing unit (CPU) 525 using a program.

In a manufacturing process of an SOI substrate used for a microprocessor and an RFCPU which are semiconductor devices of this embodiment, reprocessing treatment of a separated bond substrate is performed, whereby a plurality of semiconductor films are formed using one bond substrate; therefore, a reduction in manufacturing cost and improvement in productivity can be achieved.

Note that a structure described in this embodiment can be combined with a structure described in other embodiments as appropriate.

### Embodiment 4

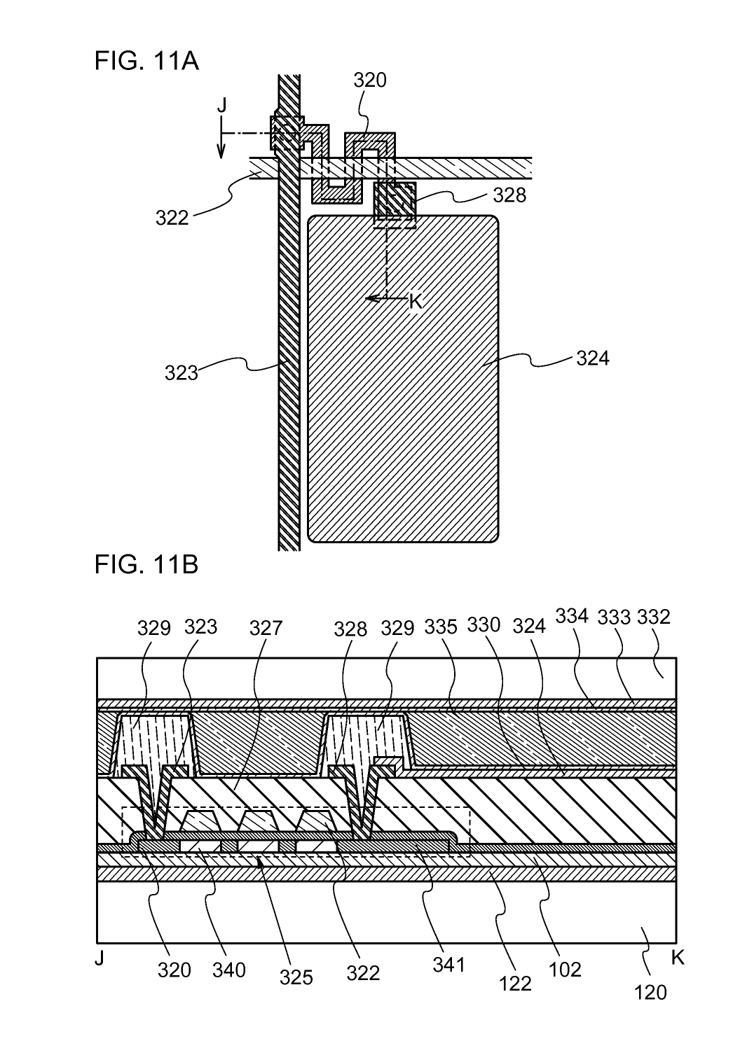

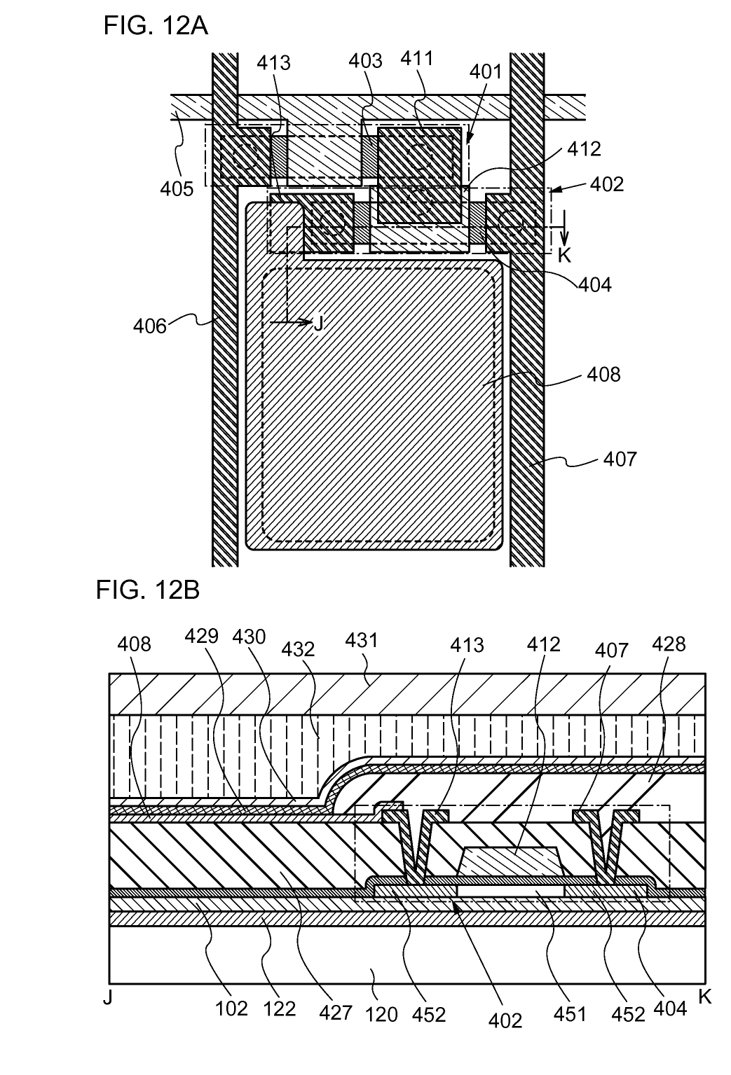

In this embodiment, a display device manufactured using an SOI substrate described in the above embodiment will be described with reference to FIGS. 11A and 11B and FIGS. 12A and 12B.

First, a liquid crystal display device will be described with reference to FIGS. 11A and 11B. FIG. 11A is a plan view of a pixel of the liquid crystal display device, and FIG. 11B is a cross-sectional view taken along a line J-K in FIG. 11A.

As illustrated in FIG. 11A, a pixel includes a single crystal semiconductor film 320, a scanning line 322 intersecting with the single crystal semiconductor film 320, a signal line 323 intersecting with the scanning line 322, a pixel electrode 324, and an electrode 328 which electrically connects the pixel electrode 324 to the single crystal semiconductor film 320. The single crystal semiconductor film 320 is a layer formed of the single crystal semiconductor film provided over a glass substrate 120 and is included in a TFT 325 of the pixel.

As an SOI substrate, the SOI substrate described in the above embodiments is used. As illustrated in FIG. 11B, the single-crystal semiconductor film 320 is stacked over the glass substrate 120 with a second insulating film 122 and a first insulating film 102 interposed therebetween. The single crystal semiconductor film 320 of the TFT 325 is formed in such a manner that a single crystal semiconductor film of the SOI substrate is isolated for each element by being etched. A channel formation region 340 and n-type high-concentration impurity regions 341 to which an impurity element is added are formed in the single crystal semiconductor film 320. A gate electrode of the TFT 325 is included in the scanning line 322 and one of a source electrode and a drain electrode of the TFT 325 is included in the signal line 323.

The signal line 323, the pixel electrode 324, and the electrode 328 are provided over an interlayer insulating film 327. Further, column spacers 329 are formed over the interlayer insulating film 327, and an orientation film 330 is formed to cover the signal line 323, the pixel electrode 324, the electrode 328, and the column spacers 329. A counter substrate 332 is provided with a counter electrode 333 and an orientation film 334 which covers the counter electrode 333. The column spacers 329 are formed to maintain a space between the glass substrate 120 and the counter substrate 332. A liquid crystal layer 335 is formed in a space which is formed by the column spacers 329. The interlayer insulating film 327 has a step at the connection portion between the n-type high-concentration impurity regions 341, and the signal line 323 and the electrode 328 due to formation of contact holes; therefore, orientation of liquid crystals in the liquid crystal layer 335 is easily disordered at this connection portion. Therefore, the column spacers 329 are formed at the step portions to prevent the disorder of the orientation of liquid crystals.

Next, an electroluminescent display device (hereinafter referred to as an EL display device) is described with reference to FIGS. 12A and 12B. FIG. 12A is a plan view of a pixel of an EL display device, and FIG. 12B is a cross-sectional view taken along a line J-K in FIG. 12A.

As illustrated in FIG. 12A, a pixel includes a TFT as a selection transistor 401; a TFT as a display control transistor 402; a scanning line 405; a signal line 406; a current supply line 407; and a pixel electrode 408. Each pixel is provided with a light-emitting element having a structure in which a layer including an electroluminescent material (an EL layer) is sandwiched between a pair of electrodes. One electrode of the light emitting element is the pixel electrode 408. Further, in a semiconductor film 403, a channel formation region, a source region, and a drain region of the selection transistor 401 are formed. Further, in a semiconductor film 404, a channel formation region, a source region, and a drain region of the display control transistor 402 are formed. The semiconductor films 403 and 404 are layers formed of the single crystal semiconductor film provided over the base substrate.

In the selection transistor 401, a gate electrode is included in the scanning line 405, one of a source electrode and a drain electrode is included in the signal line 406, and the other thereof is formed as an electrode 410. In the display control transistor 402, a gate electrode 412 is electrically connected to an electrode 411, one of a source electrode and a drain electrode is formed as an electrode 413 which is electrically connected to the pixel electrode 408, and the other thereof is included in the current supply line 407.

The display control transistor 402 is a p-channel TFT. As illustrated in FIG. 12B, a channel formation region 451 and p-type high-concentration impurity regions 452 are formed in the semiconductor film 404. As an SOI substrate, the SOI substrate manufactured by the method described in Embodiment 1 is used.

An interlayer insulating film 427 is formed so as to cover the gate electrode 412 of the display control transistor 402. Over the interlayer insulating film 427, the signal line 406, the current supply line 407, the electrode 411, the electrode 413, and the like are formed. Over the interlayer insulating film 427, the pixel electrode 408 which is electrically connected to the electrode 413 is formed. The pixel electrode 408 is surrounded by a partition wall layer 428 which has an insulating property at the periphery. An EL layer 429 is formed over the pixel electrode 408, and a counter electrode 430 is formed over the EL layer 429. A counter substrate 431 is provided as a reinforcing plate and is fixed to the glass substrate 120 with a resin layer 432.

The gray scale of the EL display device can be controlled by a current driving method in which luminance of a light-emitting element is controlled by current or a voltage driving method in which luminance of a light-emitting element is controlled by voltage. It is difficult to employ the current driving method when transistors have characteristic values which are largely different between pixels, and therefore a correction circuit which corrects variations in characteristics is needed. The EL display device is manufactured by a manufacturing process of an SOI substrate and a manufacturing method including a gettering step so that the selection transistor 401 and the display control transistor 402 do not have variation in characteristics in each pixel. Thus, the current driving method can be employed.

In a manufacturing process of an SOI substrate used for a liquid crystal display device or an EL display device which is a semiconductor device in this embodiment, reprocessing treatment of a separated bond substrate is performed, whereby a plurality of semiconductor films are formed using one bond substrate; therefore, a reduction in manufacturing cost and improvement in productivity can be achieved.

Note that a structure shown in this embodiment can be combined with a structure shown in other embodiments as appropriate.

### Embodiment 5

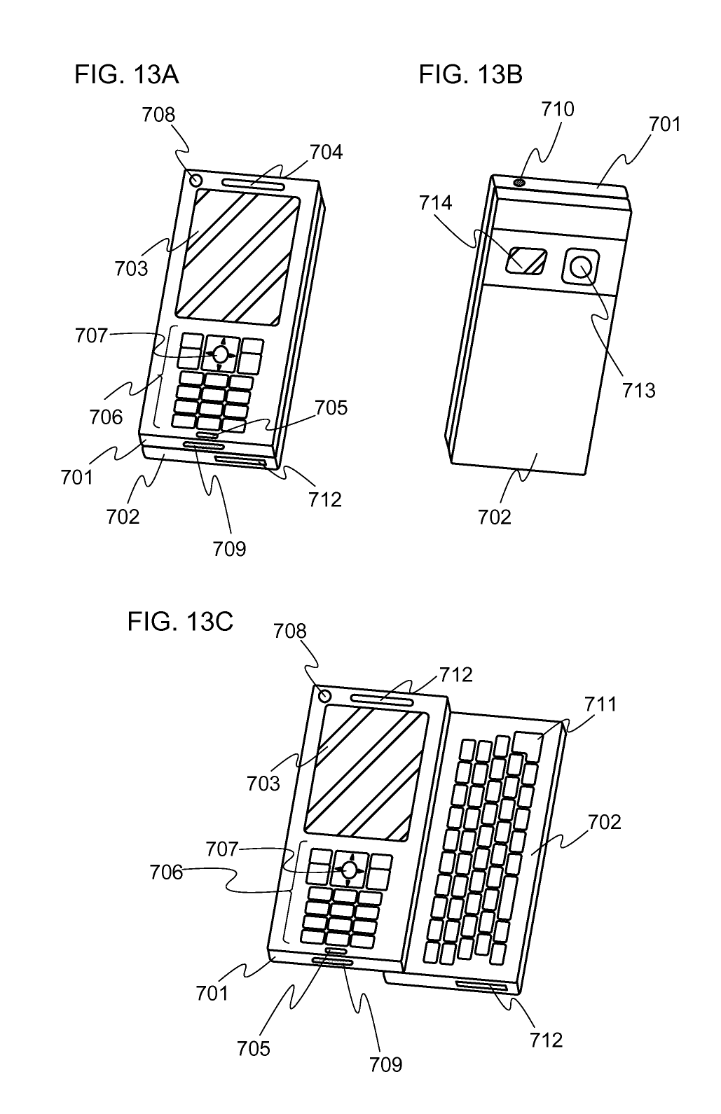

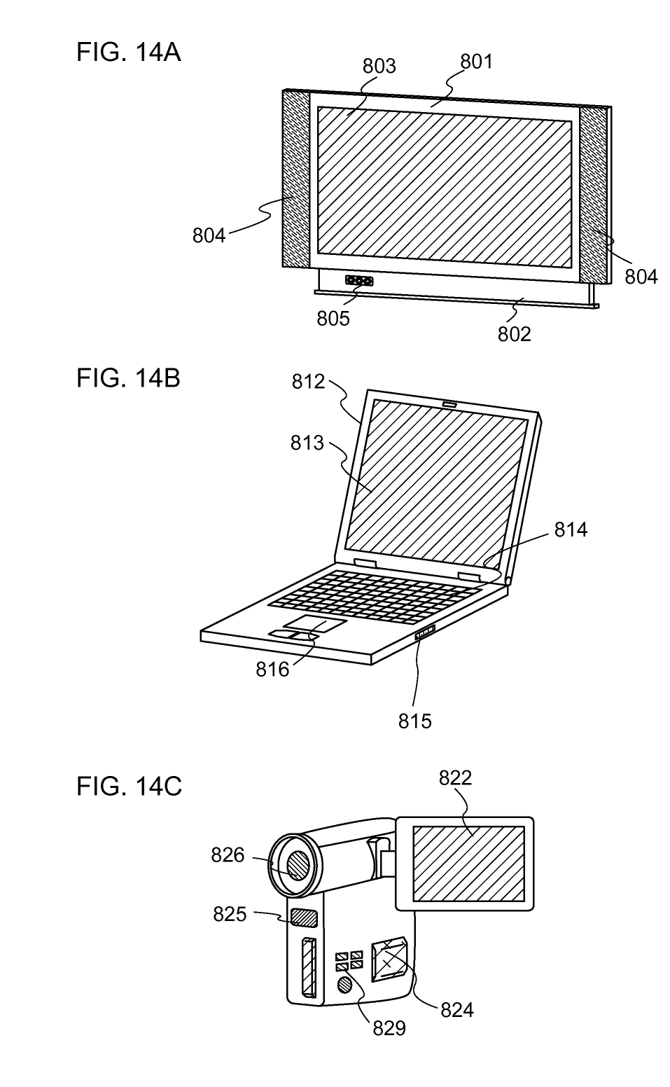

In this embodiment, electronic devices which are manufactured using an SOI substrate described in the above embodiment will be described with reference to FIGS. 13A to 13C and FIGS. 14A to 14C.

Various electronic devices can be manufactured by using SOI substrates. The electronic devices include, in its category, televisions, cameras such as video cameras and digital cameras, goggle displays (head mounted displays), navigation systems, audio reproducing devices (such as car audios or audio components), computers, desktop computers, game machines, portable information terminals (such as mobile computers, mobile phones, portable game machines, or e-book readers), and image reproducing devices having storage media (specifically, devices provided with display devices capable of playing audio data stored in recording media such as digital versatile disk (DVD) and displaying stored image data). Examples thereof are shown in FIGS. 13A to 13C and FIGS. 14A to 14C.

FIGS. 13A to 13C illustrates an example of a mobile phone. FIG. 13A is a front view, and FIG. 13B is a rear view, and FIG. 13C is a front view in which two chassis are slid. A mobile phone 700 has two chassis 701 and 702. The mobile phone 700 has both functions of a mobile phone and a portable information terminal, and incorporates a computer. The mobile phone 700 is a “smart-phone,” with which a variety of data processing is possible in addition to telephone conversation.

The mobile phone 700 has the chassis 701 and 702. The chassis 701 includes a display portion 703, a speaker 704, a microphone 705, operation keys 706, a pointing device 707, a front camera lens 708, a jack 709 for an external connection terminal, an earphone terminal 710, and the like. The chassis 702 includes a keyboard 711, an external memory slot 712, a rear camera 713, a light 714, and the like. In addition, an antenna is incorporated in the chassis 701.

Further, in addition to the above structure, the mobile phone 700 may incorporate a non-contact IC chip, a small memory device, or the like.

The chassis 701 and 702 which overlap with each other (see FIG. 13A) can be slid, and are developed by sliding as illustrated in FIG. 13C. The display panel or display device manufactured by the manufacturing method of a display device described in this embodiment can be incorporated in the display portion 703. Since the front camera lens 708 is provided in the same plane as the display portion 703, the mobile phone can be used as a videophone. Further, a still image and a moving image can be taken with the rear camera 713 and the light 714, using the display portion 703 as a viewfinder.

With the use of the speaker 704 and the microphone 705, the mobile phone 700 can be used as an audio recording device (recording device) or an audio playing device. With the use of the operation keys 706, further, operations of incoming and outgoing of calls, simple information input such as electronic mail, scrolling of a screen displayed on the display portion, cursor movement, e.g., for selecting information to be displayed in the display portion, and the like are possible.

If much information needs to be treated in documentation, a use as a portable information terminal, and the like, it is convenient to use the keyboard 711. By sliding the chassis 701 and 702 which overlap with each other (see FIG. 13A), the chassis 701 and 702 can be developed as illustrated in FIG. 13C. In using the mobile phone 700 as a portable information terminal, a cursor can be moved smoothly with use of the keyboard 711 and the pointing device 707. The jack 709 for an external connection terminal can be connected to an AC adapter or a variety of cables such as a USB cable, and charging and data communication with a personal computer or the like is possible. Further, by inserting a recording medium in the external memory slot 712, a larger amount of data can be stored and transferred.

Further, the mobile phone 700 may have an infrared communication function, a USB port, a function of receiving one segment television broadcast, a non-contact IC chip, an earphone jack, or the like, in addition to the above-described functions and structures.

FIG. 14A illustrates a display device including a chassis 801, a supporting base 802, a display portion 803, a speaker portion 804, a video input terminal 805, and the like. Note that the display device includes all devices for displaying information in its category, for example, devices for personal computers, for receiving TV broadcasting, and for displaying an advertisement.

FIG. 14B illustrates a computer, which includes a chassis 812, a display portion 813, a keyboard 814, an external connecting port 815, a pointing device 816, and the like.

FIG. 14C illustrates a video camera, which includes a display portion 822, an external connecting port 824, a remote control receiving portion 825, an image receiving portion 826, operation keys 829, and the like.

As to the variety of electric devices described in this embodiment, in a manufacturing process of an SOI substrate, reprocessing treatment of a separated bond substrate is performed, whereby a plurality of semiconductor films are formed using one bond substrate; therefore, a reduction in manufacturing cost and improvement in productivity can be achieved.

Note that a structure shown in this embodiment can be combined with a structure shown in other embodiments as appropriate.

### Example 1

In this example, a process in which a thickness non-uniformity formed on a separation surface of a separated bond substrate is removed by reprocessing treatment will be described.

In this example, a rectangular single crystal silicon substrate with a diagonal of 5 inches was used. First, thermal oxidation was performed on the single crystal silicon substrate in an oxidizing atmosphere containing HCl to form a thermal oxide film with a thickness of 100 nm.

Next, the single crystal silicon substrate was irradiated with hydrogen ions from the surface of the thermal oxide film by using an ion doping apparatus. In this example, hydrogen was ionized for irradiation to form an embrittlement layer in the single crystal silicon substrate. The ion doping was performed with an accelerating voltage of 40 kV at a dose of 2.0×10¹⁶ ions/cm².

Next, the single crystal silicon substrate was bonded to a glass substrate with the thermal oxide film interposed therebetween. After that, heat treatment at 200° C. for 120 minutes and heat treatment at 600° C. for 120 minutes were performed, so that at the embrittlement layer, the single crystal silicon substrate was separated into a thin single crystal silicon layer and a separated single crystal silicon substrate which was a remaining portion of the single crystal silicon substrate. Thus, an SOI substrate in which a single crystal silicon film was formed over the glass substrate with the thermal oxide film interposed therebetween and a separated single crystal silicon substrate which included a projection having the remaining insulating film and the remaining single crystal silicon layer in the peripheral portion were manufactured.

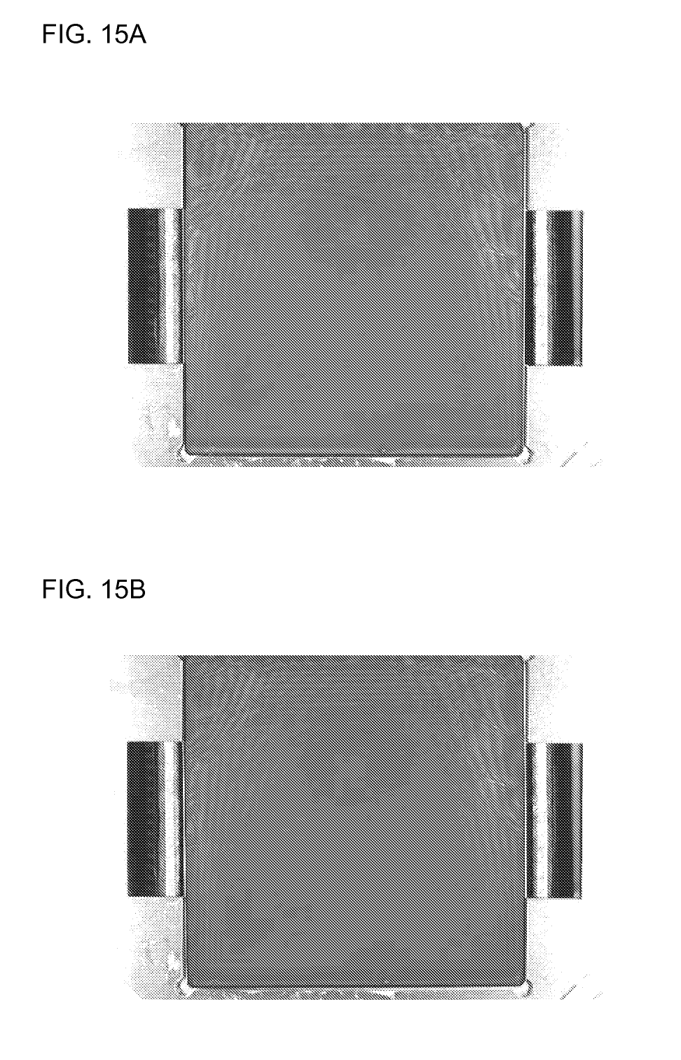

A thickness non-uniformity was observed on separation surfaces of the single crystal silicon layer and the separated single crystal silicon substrate. FIG. 15A is a photograph of the separation surface of the separated single crystal silicon substrate at this time. It is found that as illustrated in FIG. 15A, the thickness non-uniformity is formed to have a reversed C shape of which open side faces the bottom side of the substrate on the paper.

Next, wet etching was performed on the separated single crystal silicon substrate by using a mixture solution containing hydrofluoric acid, ammonium fluoride, and surfactant (product name: LAL500, manufactured by Stella Chemifa Corporation) as an etchant. At this time, the solution temperature was 20° C. and the etching time was 600 seconds. FIG. 15B is a photograph of the separation surface after the wet etching with LAL 500. As compared to that of FIG. 15A, the thickness non-uniformity is slightly more inconspicuous.

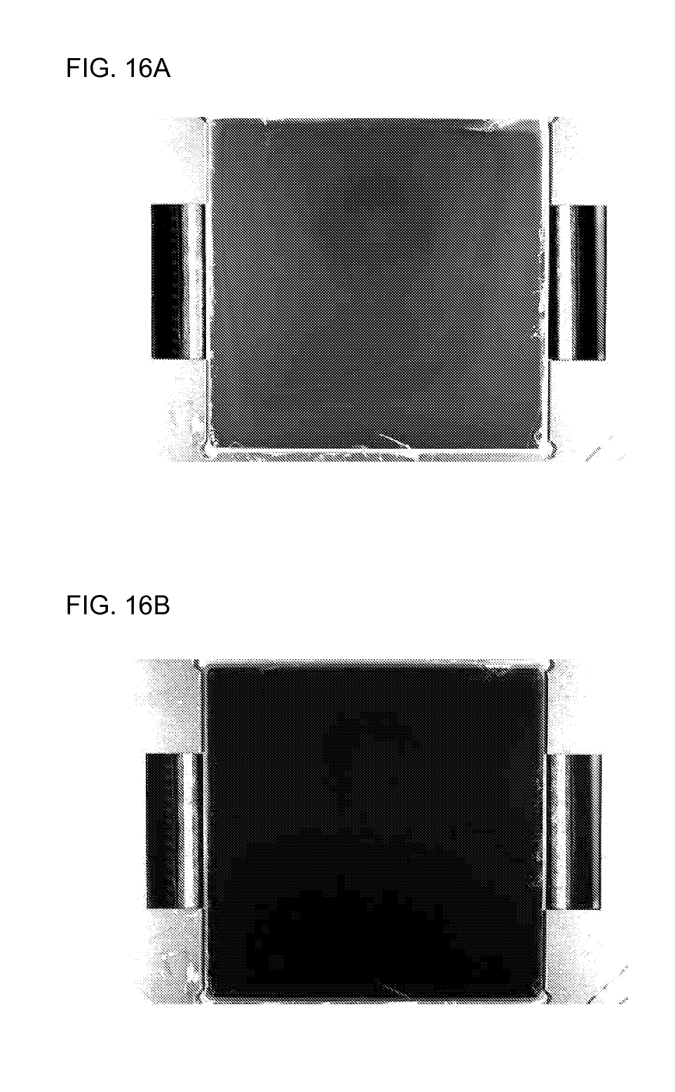

Next, wet etching was performed on the separated single crystal silicon substrate using a solution of 2.38% of tetramethylammonium hydroxide (TMAH) (Product Name: NMD3, manufactured by Tokyo Ohka Kogyo Co., Ltd.) as an etchant. At this time, the solution temperature was 50° C. and the etching time was 60 seconds. FIG. 16A is a photograph of the separation surface after the wet etching with TMAH. As compared to that of FIG. 15B, the thickness non-uniformity is almost removed but slightly observed.

Next, thermal oxidation was performed on the separated single crystal silicon substrate in an oxidizing atmosphere containing HCl. At this time, thermal oxidation was performed in an atmosphere containing HCl at 3 volume % with respect to oxygen at 950° C. for 3 hours. FIG. 16B is a photograph of the separation surface after the HCl thermal oxidation. Since the HCl thermal oxidation was performed, a thermal oxide film was observed; however, it is found that as compared to that of FIG. 16A, the thickness non-uniformity is not observed on the thermal oxide film.

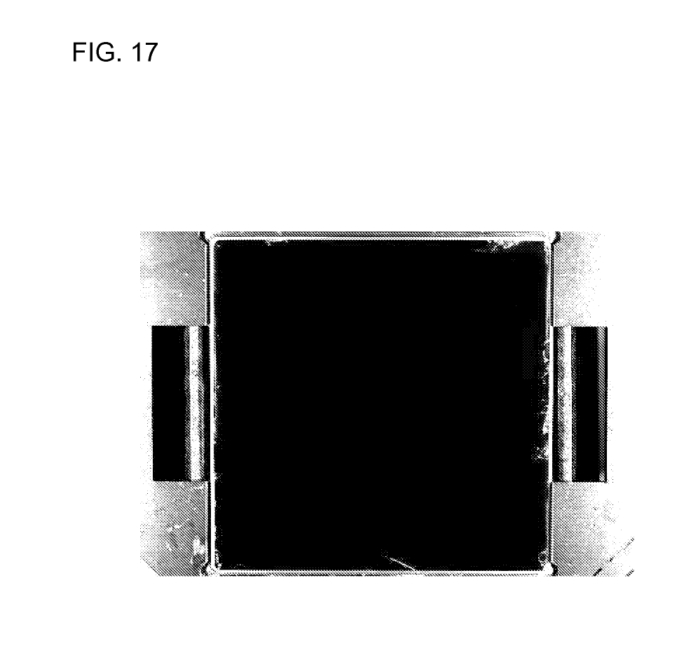

Next, wet etching was performed using a mixture solution containing hydrofluoric acid, ammonium fluoride, and a surfactant (product name: LAL500, manufactured by Stella Chemifa Corporation) as an etchant to remove the thermal oxide film. At this time, the solution temperature was 20° C. and the etching time was 600 seconds. FIG. 17 is a photograph of the separation surface after the removal of the thermal oxide film. The thickness non-uniformity on the separation surface of the separated single crystal silicon substrate cannot be recognized by eyes.

Accordingly, it is shown that by two kinds of wet etching, formation of a thermal oxide film in an oxidizing atmosphere containing HCl, and removal thereof, the thickness non-uniformity on the surface of the separated bond substrate, which are generated in the case of using a glass substrate as a base substrate, can be reduced to a level where the thickness non-uniformity on the surface of the separated bond substrate cannot be recognized by eyes.

This application is based on Japanese Patent Application serial No. 2008-189111 filed with Japan Patent Office on Jul. 22, 2008, the entire contents of which are hereby incorporated by reference.

What is claimed is:

1. A method for manufacturing an SOI substrate comprising:
forming an insulating film over a bond substrate;
adding ions into the bond substrate to form an embrittlement layer;
bonding the bond substrate to a substrate with the insulating film interposed therebetween;
separating the bond substrate into a semiconductor film which is bonded to the substrate with the insulating film interposed therebetween and a separated bond substrate at the embrittlement layer;
performing a wet etching on the separated bond substrate;
performing a thermal oxidation treatment on the separated bond substrate in an oxidizing atmosphere to which a gas containing halogen is added to form an oxide film on a surface of the separated bond substrate; and
performing a wet etching on the oxide film; and
performing a polishing on the separated bond substrate to reuse the separated bond substrate as a bond substrate.

2. The method for manufacturing an SOI substrate according to claim 1, wherein the substrate is a glass substrate selected from the group consisting of aluminosilicate glass, barium borosilicate glass, and aluminoborosilicate glass.

3. The method for manufacturing an SOI substrate according to claim 1, wherein the insulating film is a single film or a stacked layer of a plurality of films selected from silicon oxide, silicon nitride, silicon oxynitride, and silicon nitride oxide.

4. The method for manufacturing an SOI substrate according to claim 1, wherein the insulating film is silicon oxide formed by a chemical vapor deposition method using an organosilane gas.

5. The method for manufacturing an SOI substrate according to claim 1, wherein the insulating film is silicon oxide formed by performing a thermal oxidation on the bond substrate.

6. The method for manufacturing an SOI substrate according to claim 1, wherein a second insulating film is formed in contact with the substrate.

7. The method for manufacturing an SOI substrate according to claim 6, wherein the second insulating film is silicon nitride or silicon nitride oxide.

8. The method for manufacturing an SOI substrate according to claim 1, wherein the bond substrate is a single crystal silicon.

9. The method for manufacturing an SOI substrate according to claim 1, wherein HCl is used as the gas containing halogen.

10. The method for manufacturing an SOI substrate according to claim 1, wherein the oxide film contains halogen.

11. The method for manufacturing an SOI substrate according to claim 1, wherein a chemical mechanical polishing (CMP) method is used as the polishing.

12. The method for manufacturing an SOI substrate according to claim 1, wherein the SOI substrate is incorporated in at least one selected from the group consisting of a display device, a phone, a computer, and a camera.

13. A method for manufacturing an SOI substrate comprising:
forming an insulating film over a bond substrate;
adding ions into the bond substrate to form an embrittlement layer;
bonding the bond substrate to a substrate with the insulating film interposed therebetween;
separating the bond substrate into a semiconductor film which is bonded to the substrate with the insulating film interposed therebetween and a separated bond substrate at the embrittlement layer;
performing a first wet etching using a solution containing hydrofluoric acid on the separated bond substrate;
performing a second wet etching using an organic alkaline aqueous solution on the separated bond substrate;
performing a thermal oxidation treatment on the separated bond substrate in an oxidizing atmosphere to which a gas containing halogen is added to form an oxide film on a surface of the separated bond substrate;
performing a third wet etching using a solution containing hydrofluoric acid on the oxide film; and
performing a polishing on the separated bond substrate to reuse the separated bond as a bond substrate.

14. The method for manufacturing an SOI substrate according to claim 13, wherein the substrate is a glass substrate selected from the group consisting of aluminosilicate glass, barium borosilicate glass, and aluminoborosilicate glass.

15. The method for manufacturing an SOI substrate according to claim 13, wherein the solution containing hydrofluoric acid is a mixed solution containing hydrofluoric acid, ammonium fluoride, and a surfactant.

16. The method for manufacturing an SOI substrate according to claim 13, wherein the organic alkaline aqueous solution is a solution containing tetramethylammonium hydroxide.

17. The method for manufacturing an SOI substrate according to claim 13, wherein the insulating film is a single film or a stacked layer of a plurality of films selected from silicon oxide, silicon nitride, silicon oxynitride, and silicon nitride oxide.

18. The method for manufacturing an SOI substrate according to claim 13, wherein the insulating film is the silicon oxide film which is formed by a chemical vapor deposition method using an organosilane gas.

19. The method for manufacturing an SOI substrate according to claim 13, wherein the insulating film is the silicon oxide film which is formed by performing thermal oxidation on the bond substrate.

20. The method for manufacturing an SOI substrate according to claim 13, wherein a second insulating film is formed in contact with the substrate.

21. The method for manufacturing an SOI substrate according to claim 20, wherein the second insulating film is silicon nitride or silicon nitride oxide.

22. The method for manufacturing an SOI substrate according to claim 13, wherein the bond substrate is a single crystal silicon.

23. The method for manufacturing an SOI substrate according to claim 13, wherein HCl is used as the gas containing halogen.

24. The method for manufacturing an SOI substrate according to claim 13, wherein the oxide film contains halogen.

25. The method for manufacturing an SOI substrate according to claim 13, wherein a chemical mechanical polishing (CMP) method is used as the polishing.

26. The method for manufacturing an SOI substrate according to claim 13, wherein the SOI substrate is incorporated in at least one selected from the group consisting of a display device, a phone, a computer, and a camera.

27. A method for manufacturing an SOI substrate comprising:
forming an insulating film over a bond substrate;
adding ions into the bond substrate to form an embrittlement layer;
bonding the bond substrate to a substrate with the insulating film interposed therebetween;
separating the bond substrate into a semiconductor film which is bonded to the substrate with the insulating film interposed therebetween and a separated bond substrate at the embrittlement layer;
performing a first wet etching using a solution containing hydrofluoric acid on the separated bond substrate;
performing a second wet etching using an organic alkaline aqueous solution on the separated bond substrate;
performing a thermal oxidation treatment on the separated bond substrate in an oxidizing atmosphere to which a gas containing halogen is added to form an oxide film on a surface of the separated bond substrate; and
performing a third wet etching using a solution containing hydrofluoric acid on the oxide film to remove thickness non-uniformity generated on a separation surface of the separated bond substrate in separating the bond substrate.

28. The method for manufacturing an SOI substrate according to claim 27, wherein the substrate is a glass substrate selected from the group consisting of aluminosilicate glass, barium borosilicate glass, and aluminoborosilicate glass.

29. The method for manufacturing an SOI substrate according to claim 27, wherein the solution containing hydrofluoric acid is a mixed solution containing hydrofluoric acid, ammonium fluoride, and a surfactant.

30. The method for manufacturing an SOI substrate according to claim 27, wherein the organic alkaline aqueous solution is a solution containing tetramethylammonium hydroxide.

31. The method for manufacturing an SOI substrate according to claim 27, wherein the insulating film is a single film or a stacked layer of a plurality of films selected from silicon oxide, silicon nitride, silicon oxynitride, and silicon nitride oxide.

32. The method for manufacturing an SOI substrate according to claim 27, wherein the insulating film is the silicon oxide film which is formed by a chemical vapor deposition method using an organosilane gas.

33. The method for manufacturing an SOI substrate according to claim 27, wherein the insulating film is the silicon oxide film which is formed by performing thermal oxidation on the bond substrate.

34. The method for manufacturing an SOI substrate according to claim 27, wherein a second insulating film is formed in contact with the substrate.

35. The method for manufacturing an SOI substrate according to claim 34, wherein the second insulating film is silicon nitride or silicon nitride oxide.

36. The method for manufacturing an SOI substrate according to claim 27, wherein the bond substrate is a single crystal silicon.

37. The method for manufacturing an SOI substrate according to claim 27, wherein HCl is used as the gas containing halogen.

38. The method for manufacturing an SOI substrate according to claim 27, wherein the oxide film contains halogen.

39. The method for manufacturing an SOI substrate according to claim 27, wherein a chemical mechanical polishing (CMP) method is used as the polishing.

40. The method for manufacturing an SOI substrate according to claim 27, wherein the SOI substrate is incorporated in at least one selected from the group consisting of a display device, a phone, a computer, and a camera.

41. A method for manufacturing an SOI substrate comprising:
forming an insulating film over a bond substrate;
adding ions into the bond substrate to form an embrittlement layer;
bonding the bond substrate to a substrate with the insulating film interposed therebetween;
separating the bond substrate into a semiconductor film which is bonded to the substrate with the insulating film interposed therebetween and a separated bond substrate at the embrittlement layer;
performing a first wet etching using a solution containing hydrofluoric acid on the separated bond substrate;
performing a second wet etching using an organic alkaline aqueous solution on the separated bond substrate;
performing a thermal oxidation treatment on the separated bond substrate in an oxidizing atmosphere to which a gas containing halogen is added to form an oxide film on a surface of the separated bond substrate; and
performing a third wet etching using a solution containing hydrofluoric acid on the oxide film;
performing a polishing on the separated bond substrate; and
removing the remaining semiconductor film and the remaining insulating film in the peripheral portion of the separated bond substrate in separating the bond substrate.

42. The method for manufacturing an SOI substrate according to claim 41, wherein the substrate is a glass substrate selected from the group consisting of aluminosilicate glass, barium borosilicate glass, and aluminoborosilicate glass.

43. The method for manufacturing an SOI substrate according to claim 41, wherein the solution containing hydrofluoric acid is a mixed solution containing hydrofluoric acid, ammonium fluoride, and a surfactant.

44. The method for manufacturing an SOI substrate according to claim 41, wherein the organic alkaline aqueous solution is a solution containing tetramethylammonium hydroxide.

45. The method for manufacturing an SOI substrate according to claim 41, wherein the insulating film is a single film or a stacked layer of a plurality of films selected from silicon oxide, silicon nitride, silicon oxynitride, and silicon nitride oxide.

46. The method for manufacturing an SOI substrate according to claim 41, wherein the insulating film is the silicon oxide film which is formed by a chemical vapor deposition method using an organosilane gas.

47. The method for manufacturing an SOI substrate according to claim 41, wherein the insulating film is the silicon oxide film which is formed by performing thermal oxidation on the bond substrate.

48. The method for manufacturing an SOI substrate according to claim 41, wherein a second insulating film is formed in contact with the substrate.

49. The method for manufacturing an SOI substrate according to claim 48, wherein the second insulating film is silicon nitride or silicon nitride oxide.

50. The method for manufacturing an SOI substrate according to claim 41, wherein the bond substrate is a single crystal silicon.

51. The method for manufacturing an SOI substrate according to claim 41, wherein HCl is used as the gas containing halogen.

52. The method for manufacturing an SOI substrate according to claim 41, wherein the oxide film contains halogen.

53. The method for manufacturing an SOI substrate according to claim 41, wherein a chemical mechanical polishing (CMP) method is used as the polishing.

54. The method for manufacturing an SOI substrate according to claim 41, wherein the SOI substrate is incorporated in at least one selected from the group consisting of a display device, a phone, a computer, and a camera.
